(19) United States
(12) Patent Application Publication
(10) Pub. No.: US 2025/0293648 A1
(43) Pub. Date: Sep. 18, 2025

(54) METHODS AND APPARATUS TO OPERATE A BUFFER STAGE IN AMPLIFIER CIRCUITRY

(71) Applicant: Texas Instruments Incorporated, Dallas, TX (US)

(72) Inventors: Tyler James Archer, Vail, AZ (US); Bharath Karthik Vasan, Tucson, AZ (US)

(21) Appl. No.: 18/963,143

(22) Filed: Nov. 27, 2024

Related U.S. Application Data
(60) Provisional application No. 63/564,629, filed on Mar. 13, 2024.
(60) Provisional application No. 63/564,637, filed on Mar. 13, 2024.

(51) Int. Cl. H03F 3/45

(52) U.S. Cl. CPC H03F 3/45179; H03F 2203/45112; H03F 2203/45476

(57) ABSTRACT

An example apparatus includes: buffer circuitry including: a first transistor having a first terminal, a second terminal, and a control terminal; and a second transistor having a first terminal, a second terminal, and a control terminal, the first terminal of the second transistor coupled to the first terminal of the first transistor, the control terminal of the second transistor coupled to the control terminal of the first transistor; output stage circuitry including: gate biasing circuitry having a terminal; a third transistor having a first terminal and a control terminal, the control terminal of the third transistor coupled to the second terminal of the second transistor and the terminal of the gate biasing circuitry; current mirror circuitry having an input and an output, the input of the current mirror circuitry coupled to the second terminal of the first transistor.

### CROSS-REFERENCE TO RELATED APPLICATION

This patent application claims the benefit of and priority to U.S. Provisional Patent Application No. 63/564,629 filed Mar. 13, 2024, and U.S. Provisional Patent Application No. 63/564,637 filed Mar. 13, 2024, which are each hereby incorporated herein by reference in their entirety.

### TECHNICAL FIELD

This description relates generally to amplifiers and, more particularly, to methods and apparatus to operate a buffer stage in amplifier circuitry.

### BACKGROUND

Amplifier circuitry generates relatively high-power signals at an output responsive to relatively low power signals at an input. In some devices, amplifier circuitry regulates the supply of power to circuitry. In other devices, amplifier circuitry allows relatively low-power circuitry to interface with relatively high-power circuitry. Amplifier circuitry utilizes increasingly complex circuitry to support higher output voltages, output currents, and operating speeds. Such circuitry allows amplifier circuitry to safely support a wide range of operating conditions.

### SUMMARY

For methods and apparatus to operate a buffer stage in amplifier circuitry, an example apparatus includes buffer circuitry including: a first transistor having a first terminal, a second terminal, and a control terminal; a second transistor having a first terminal, a second terminal, and a control terminal, the control terminal of the second transistor coupled to the control terminal of the first transistor; a third transistor having a first terminal and a control terminal, the control terminal of the third transistor coupled to the first terminal of the first transistor; and a fourth transistor having a first terminal and a control terminal, the first terminal of the fourth transistor coupled to the first terminal of the third transistor, the control terminal of the fourth transistor coupled to the first terminal of the second transistor; and output stage circuitry including: first gate biasing circuitry having a terminal coupled to the second terminal of the first transistor; second gate biasing circuitry having a terminal coupled to the second terminal of the second transistor; a fifth transistor having a control terminal coupled to the second terminal of the first transistor and the terminal of the first gate biasing circuitry; and a sixth transistor having a control terminal coupled to the second terminal of the second transistor and the terminal of the second gate biasing circuitry. Other examples are described.

For methods and apparatus to operate a buffer stage in amplifier circuitry, an example apparatus includes buffer circuitry including: a first transistor having a first terminal, a second terminal, and a control terminal; a second transistor having a first terminal, a second terminal, and a control terminal, the control terminal of the second transistor coupled to the control terminal of the first transistor; a third transistor having a first terminal, a second terminal, and a control terminal, the control terminal of the third transistor coupled to the first terminal of the first transistor; and a fourth transistor having a first terminal, a second terminal, and a control terminal, the first terminal of the fourth transistor coupled to the first terminal of the third transistor, the control terminal of the fourth transistor coupled to the first terminal of the second transistor; first current mirror circuitry having an input and an output, the input of the first current mirror circuitry coupled to the second terminal of the first transistor and the second terminal of the fourth transistor; second current mirror circuitry having an input and an output, the input of the second current mirror circuitry coupled to the second terminal of the second transistor and the second terminal of the third transistor; a fifth transistor having a first terminal and a control terminal, the control terminal of the fifth transistor coupled to the output of the first current mirror circuitry; and a sixth transistor having a first terminal and a control terminal, the first terminal of the sixth transistor coupled to the first terminal of the fifth transistor, the control terminal of the sixth transistor coupled to the output of the second current mirror circuitry. Other examples are described.

For methods and apparatus to operate a buffer stage in amplifier circuitry, an example apparatus includes buffer circuitry including: a first transistor having a first terminal, a second terminal, and a control terminal; and a second transistor having a first terminal, a second terminal, and a control terminal, the first terminal of the second transistor coupled to the first terminal of the first transistor, the control terminal of the second transistor coupled to the control terminal of the first transistor; output stage circuitry including: gate biasing circuitry having a terminal; a third transistor having a first terminal and a control terminal, the control terminal of the third transistor coupled to the second terminal of the second transistor and the terminal of the gate biasing circuitry; current mirror circuitry having an input and an output, the input of the current mirror circuitry coupled to the second terminal of the first transistor; and a fourth transistor having a control terminal coupled to the output of the current mirror circuitry and the first terminal of the third transistor. Other examples are described.

### BRIEF DESCRIPTION OF THE DRAWINGS

FIG. 1 is a block diagram of example amplifier circuitry having an input stage, an opposed-buffer stage, and an output stage.

FIG. 2 is a schematic diagram of example amplifier circuitry including an example of the opposed-buffer stage of FIG. 1, an example of the output stage of FIG. 1, and example control signal generation circuitry.

FIG. 3 is a schematic diagram of an example of the opposed-buffer stage of FIGS. 1 and 2 including example buffer circuitry and example switch circuitry.

FIG. 4 is a schematic diagram of an example of the opposed-buffer stage of FIGS. 1, 2, and 3 including an example of the buffer circuitry of FIG. 3 and an example of the switch circuitry of FIG. 3.

FIG. 5 is a schematic diagram of an example of the opposed-buffer stage of FIGS. 1, 2, 3, and 4 including an example of the buffer circuitry of FIGS. 3 and 4, an example of the switch circuitry of FIGS. 3 and 4, and example current mirror circuitry.

FIG. 6 is a schematic diagram of example amplifier circuitry including an example of the input stage of FIG. 1 and an example of the opposed-buffer stage of FIGS. 1, 2, 3, 4, and 5.

FIG. 7A is a schematic diagram of an example of the control signal generation circuitry of FIG. 2.

FIG. 7B is a timing diagram of example operations of the control signal generation circuitry of FIGS. 2 and 7A.

FIG. 8 is a flowchart representative of example machine-readable instructions or example operations that may be at least one of executed, instantiated, or performed using an example implementation of the opposed-buffer stages of FIGS. 1, 2, 3, 4, 5, and 6, the control signal generation circuitry of FIGS. 2 and 7A, or more generally the amplifier circuitry of FIGS. 1 and 2.

FIG. 9 is a timing diagram of example operations of the opposed-buffer stages of FIGS. 1, 2, 3, 4, 5, and 6, the control signal generation circuitry of FIGS. 2 and 7A, or more generally the amplifier circuitry of FIGS. 1 and 2.

FIG. 10 is a schematic diagram of example amplifier circuitry including an example of the opposed-buffer stage of FIG. 1 and the output stage of FIG. 1.

FIG. 11 is a schematic diagram of example amplifier circuitry including an example of the opposed-buffer stage of FIGS. 1 and 10 and the output stage of FIGS. 1 and 10.

FIG. 12 is a schematic diagram of example amplifier circuitry including an example of the opposed-buffer stage of FIGS. 1, 10, and 11 and the output stage of FIGS. 1, 10, and 11.

FIG. 13 is a schematic diagram of example amplifier circuitry including an example of the opposed-buffer stage of FIGS. 1, 10, 11, and 12 and the output stage of FIGS. 1, 10, 11, and 12.

FIG. 14 is a flowchart representative of example machine-readable instructions or example operations that may be at least one of executed, instantiated, or performed using an example implementation of the opposed-buffer stages of FIGS. 1, 10, 11, 12, and 13, the output stages of FIGS. 1, 10, 11, 12, and 13, or more generally the amplifier circuitry of FIGS. 1, 10, 11, 12, and 13.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Amplifier circuitry generates relatively high-power signals at an output responsive to relatively low power signals at an input. In some devices, amplifier circuitry regulates the supply of power to circuitry. In other devices, amplifier circuitry allows relatively low-power circuitry to interface with relatively high-power circuitry. Amplifier circuitry utilizes increasingly complex circuitry to support higher output voltages, output currents, and operating speeds. Such circuitry allows amplifier circuitry to safely support a wide range of operating conditions.

In some implementations, amplifier circuitry has a first input (also referred to as a non-inverting input), a second input (also referred to as an inverting input), and an output. The amplifier circuitry generates an output voltage responsive to a difference between voltages at the first and second inputs. In some systems, the amplifier circuitry amplifies the voltage at the inputs responsive to an external feedback path between the inverting input and the output. In such systems, it is advantageous to implement amplifier circuitry that is power efficient, area efficient, supports a wide bandwidth, and capable of linearly operating. One such type of amplifier circuitry is three stage amplifier circuitry.

Three stage amplifier circuitry includes an input stage, an opposed-buffer stage, and an output stage. The input stage receives an input voltage at the first and second inputs of the amplifier circuitry. Some input stages use transconductance circuitry to set the first and second inputs as high-impedance inputs. In some amplifier circuitry, the input stage produces inverting and non-inverting input voltages responsive to currents of the transconductance circuitry. In such amplifier circuitry, the input stage supplies the inverting and non-inverting input voltages to the opposed-buffer stage. In other amplifier circuitry, the input stage produces an input stage voltage responsive to currents of the transconductance circuitry. In such amplifier circuitry, the input stage provides the input stage voltage at a first input of the opposed-buffer stage and a second input of the opposed-buffer stage is set to a reference voltage.

In an example, the opposed-buffer stage includes first buffer circuitry and second buffer circuitry. The first buffer circuitry has an input coupled to a first output of the input stage, which supplies one of the non-inverting input voltage or the reference voltage. The second buffer circuitry has an input coupled to a second output of the input stage, which supplies one of the inverting input voltage or the input stage voltage. In some examples, such as for a single output input stage, one of the first or second inputs of the opposed buffer stage is coupled to a reference voltage. The output of the first buffer circuitry is coupled to the output of the second buffer circuitry by a resistor. Such a structure of the first and second buffer circuitry may be referred to as opposed buffers or opposed buffer circuitry. In operation, the first buffer circuitry produces an inverting sink current at a first supply terminal and a non-inverting source current at a second supply terminal responsive to the voltage at the inputs of the opposed buffer stage. Similarly, the second buffer circuitry produces a non-inverting sink current at a first supply terminal and an inverting source current at a second supply terminal responsive to the voltage at the inputs of the opposed buffer stage. In such operations, the difference between the inverting and non-inverting sink currents and the inverting and non-inverting source currents represents the voltage difference between inputs of the second and first buffer circuitry. The opposed-buffer stage circuitry supplies the inverting and non-inverting source currents to the output stage and sinks the inverting and non-inverting sink currents from the output stage.

In an example, the output stage includes first current mirror circuitry, second current mirror circuitry, first gate biasing circuitry, second gate biasing circuitry, class AB control circuitry, and output driver circuitry. The first current mirror circuitry mirrors the inverting sink current to supply the non-inverting sink current to the opposed-buffer stage. The first current mirror circuitry routes the difference between the inverting and non-inverting sink currents to the class AB control circuitry and the output driver circuitry. Similarly, the second current mirror circuitry mirrors the non-inverting source current to sink the inverting source current from the opposed-buffer stage. The second current mirror circuitry routes the difference between the non-inverting and inverting source currents to the class AB control circuitry and the output driver circuitry.

The first gate biasing circuitry uses a first bias current to generate a first gate bias voltage in reference to a supply voltage. The second gate biasing circuitry uses a second bias current to generate a second gate bias voltage in reference to a common potential (e.g., ground, VSS, etc.). The class AB control circuitry uses the first and second gate bias voltages to drive a pair of transistors of the output driver circuitry in a linear region. The class AB control circuitry linearly operates the pair of transistors (also referred to as high and low side transistors) by conducting the remaining portions of the inverting and non-inverting source and sink currents from the first and second current mirror circuitry. However, to continue to operate in the linear region when the inverting and non-inverting sink currents are substantially similar, such as relatively low voltages at the input of the amplifier circuitry, the class AB control circuitry uses third and fourth bias currents. The third bias current increases the current at the output of the first current mirror circuitry and the fourth bias current increases the current at the output of the second current mirror circuitry. The third and fourth bias currents improve the likelihood of the class AB control circuitry linearly controlling the transistors of the output driver circuitry. To support the operations of the amplifier circuitry the system on chip (SoC) includes four additional current sources to generate the first, second, third, and fourth bias currents. Such additional current sources increase power consumption, the system on chip size, complexity, cost, etc.

Some output stages further include a first switch and a second switch. The first switch is coupled between the gate and source terminals of the high-side transistor of the output driver circuitry. The second switch is coupled between the gate and source terminals of the low-side transistor of the output driver circuitry. In operation, closing the first and second switches disables the output of the amplifier circuitry responsive to shorting the gate and source terminals of the high and low side transistors. Such operations are referred to as a power down state or a standby state. In the power down state, the first and second switches prevent the output driver circuitry from generating a voltage at the output of the amplifier circuitry.

Also, in the power down state, the first switch shorts the class AB control circuitry and the output of the first current mirror circuitry to the supply voltage. Similarly, the second switch shorts the class AB control circuitry and the output of the second current mirror circuitry to the common potential. In such a state, the first and second switches disable the output stage, which prevents the amplifier circuitry from forming an external feedback loop. Without the external feedback loop, voltages at the inputs of the opposed-buffer stage increase, which saturates currents at the output of the first and second current mirror circuitry. However, during the transition from the power down state to normal operations, where the first and second switches are opened, relatively large differences between the non-inverting and inverting source currents or the non-inverting and inverting sink currents begin to drive the high and low side transistors. The output driver circuitry produces a transient voltage at the output of the amplifier circuitry responsive to the saturated currents. In some devices, the transient voltage may damage or inaccurately drive circuitry coupled to the output of the amplifier circuitry.

Examples described herein include methods and apparatus to operate an opposed-buffer stage in amplifier circuitry. In some examples, the opposed-buffer stage further includes first buffer circuitry, second buffer circuitry, third buffer circuitry, and switch circuitry. The first and second buffer circuitry are structured as opposing buffers and have inputs structured to be coupled to an input stage. The third buffer circuitry and the switch circuitry are coupled between the input of the first buffer circuitry and the input of the second buffer circuitry.

When in a power down state, the switch circuitry is closed to have the buffer circuitry set the input of the second buffer circuitry equal to the input of the first buffer circuitry. Also, during powered down operations, a first and second switch of the output stage are closed to disable (e.g., turn off, no longer conduct, etc.) high and low side transistors. In such examples, the first and second switch prevent the high and low side transistors from driving the output of the amplifier circuitry. During a transition from the power down state to normal operations, the first and second switch are opened at a first time. At the first time, the switch circuitry remains closed to continue to have the third buffer circuitry drive the input of the second buffer based on the input of the first buffer, which reduces the differences between the non-inverting and inverting source and sink currents. At a second time after the amplifier has settled, the switch circuitry is opened to no longer drive the input of the second buffer circuitry. Advantageously, the third buffer circuitry and the switch circuitry reduce voltage transients at the output of the amplifier circuitry during transitions from the power down state to normal operations.

In some described examples, the first and second buffer circuitry further include a first transistor, a second transistor, a third transistor, and a fourth transistor. The control terminals of the first and second transistors are coupled to the input of the buffer circuitry, which supplies an input voltage. The first transistor controls the third transistor by shifting the input voltage. The voltage shift of the first transistor is responsive to a first bias current. The third transistor conducts one of the inverting or non-inverting sink currents responsive to the voltage of the first transistor. Similarly, the second transistor controls the fourth transistor by shifting the input voltage. The voltage shift of the second transistor is responsive to a second bias current. The fourth transistor conducts one of the inverting or non-inverting source currents responsive to the voltage of the second transistor. The third and fourth transistors set the output of the buffer circuitry using the conducted currents.

In such described examples, the first transistor is coupled to one of first current mirror circuitry or first gate biasing circuitry of the output stage. The first transistor supplies the first bias current to one of the first current mirror circuitry or the first gate biasing circuitry. Similarly, the second transistor is coupled to one of second current mirror circuitry or second gate biasing circuitry of the output stage. The second transistor sinks the second bias current from the one of the second current mirror circuitry or the second gate biasing circuitry.

Advantageously, the output stage uses the first and second bias currents from the first and second transistors to bias class AB control circuitry and the output driver circuitry. Advantageously, the first and second transistors reduce the number of bias currents needed by the output stage responsive to reusing the first and second bias currents. Advantageously, as further described below, the buffer circuitry may include additional transistors to further reduce the number of bias currents needed for the output stage.

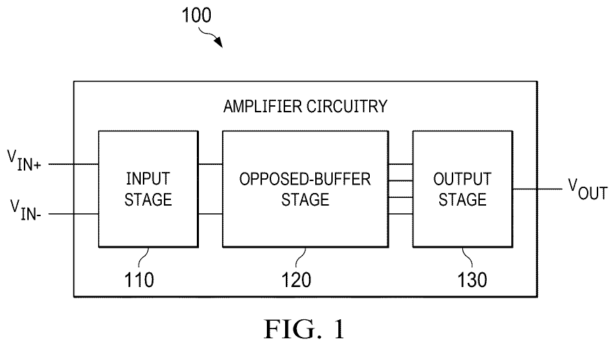

FIG. 1 is a block diagram of example amplifier circuitry 100. In the example of FIG. 1, the amplifier circuitry 100 includes an example input stage 110, an example opposed-buffer stage 120, and example output stage 130. The amplifier circuitry 100 includes a first input, a second input and an output. The first input of the amplifier circuitry 100 (also referred to as a non-inverting input) is structured to be coupled to external circuitry, which supplies a non-inverting input signal (V_{IN+}). The second input of the amplifier circuitry 100 (also referred to as an inverting input) is structured to be coupled to external circuitry, which supplies an inverting input signal (V_{IN-}). The output of the amplifier circuitry 100 is structured to be coupled to downstream circuitry, which receives an output signal (V_{OUT}).

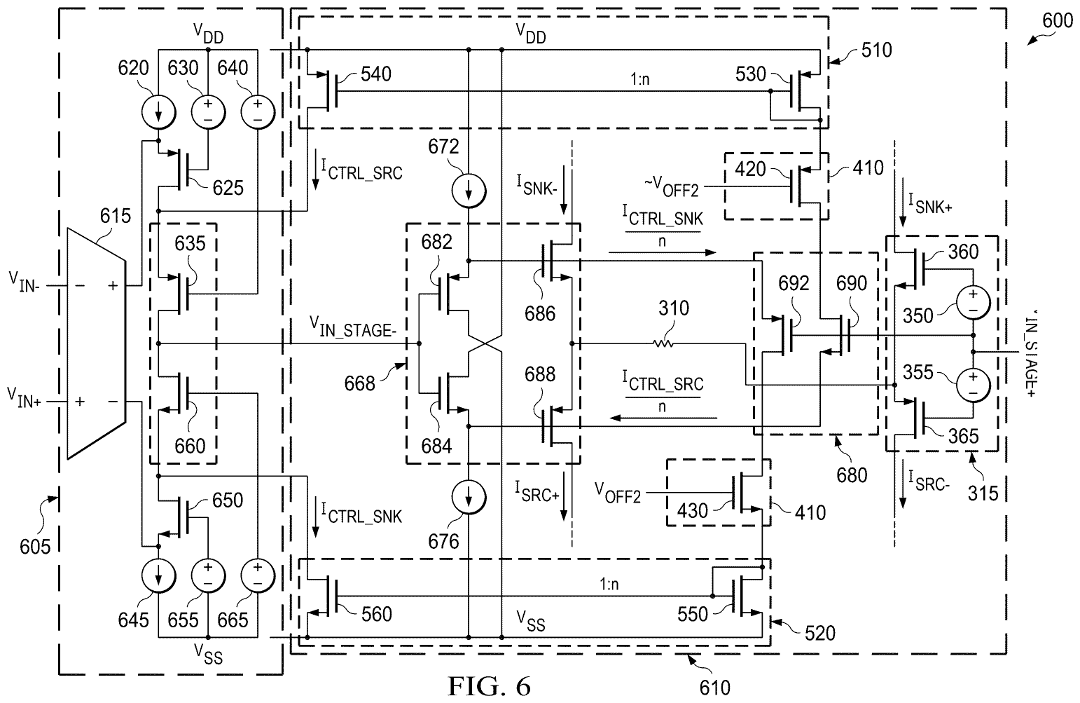

The input stage 110 has a first terminal, a second terminal, a third terminal, and a fourth terminal. The first terminal of the input stage 110 is coupled to the first input of the amplifier circuitry 100, which supplies the non-inverting input signal. The second terminal of the input stage 110 is coupled to the second input of the amplifier circuitry 100, which supplies the inverting input signal. The third and fourth terminals of the input stage 110 are coupled to the opposed-buffer stage 120. In some examples, the input stage 110 has a single output coupled to the opposed-buffer stage 120. In such examples, the input stage 110 may only have three terminals with the third terminal coupled to the opposed-buffer stage 120. Such examples are further illustrated and described in connection with FIGS. 6, 10, 11, 12, and 13. An example of the input stage 110 is further illustrated and described in connection with FIG. 6.

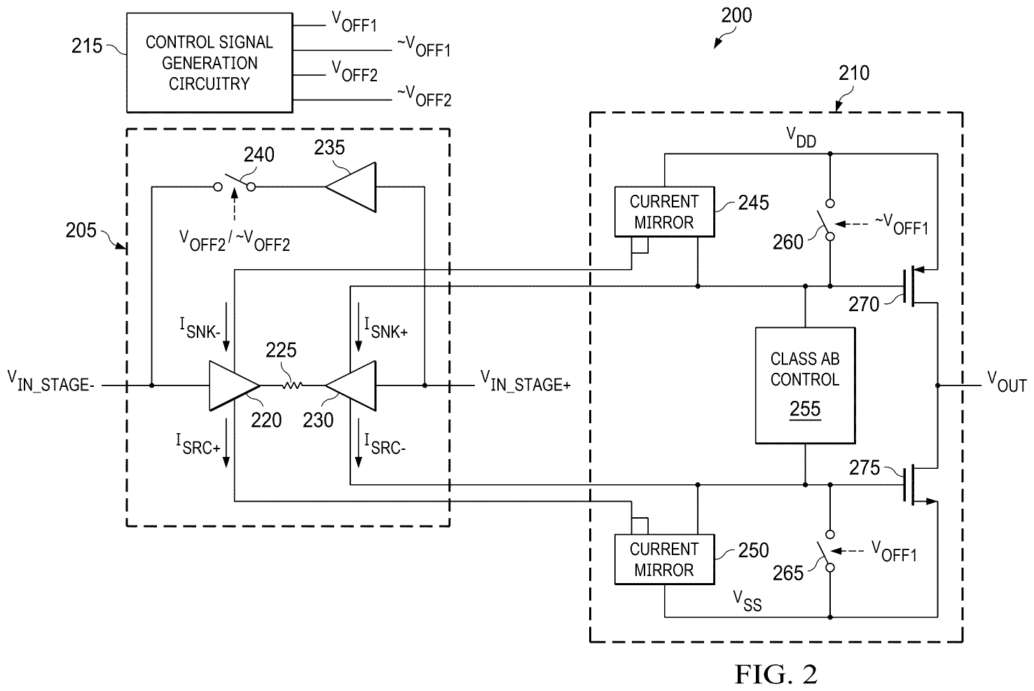

The opposed-buffer stage 120 has a first terminal, a second terminal, a third terminal, a fourth terminal, a fifth terminal, and a sixth terminal. The first and second terminals of the opposed-buffer stage 120 are coupled to the input stage 110. In some examples, the opposed-buffer stage 120 has a first terminal coupled to the input stage 110 and a second terminal coupled to a reference terminal, which supplies a reference voltage. Such examples are further illustrated and described in connection with FIGS. 6, 10, 11, 12, and 13. The third, fourth, fifth, and sixth terminals of the opposed-buffer stage 120 are coupled to the output stage 130. Examples of the opposed-buffer stage 120 are further illustrated and described in connection with FIGS. 2, 3, 4, 5, 6, 10, 11, 12, and 13.

The output stage 130 has a first terminal, a second terminal, a third terminal, a fourth terminal, and a fifth terminal. The first, second, third, and fourth terminals of the output stage 130 are coupled to the opposed-buffer stage 120. The fifth terminal of the output stage 130 is coupled to the output of the amplifier circuitry 100. Examples of the output stage 130 are further illustrated and described in connection with FIGS. 2, 10, 11, 12, and 13.

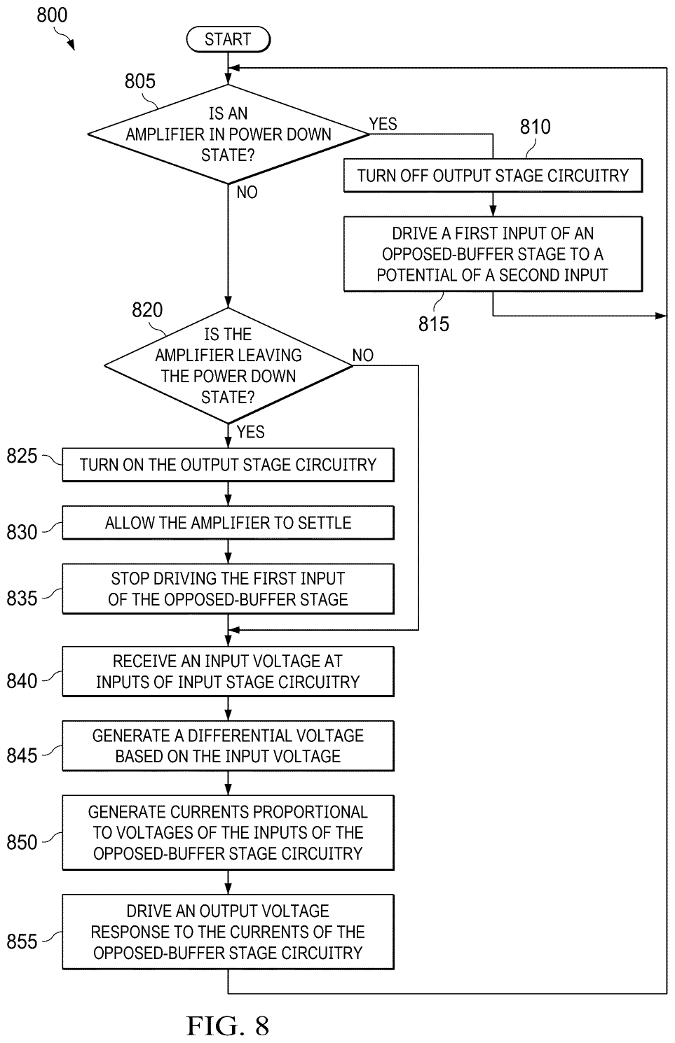

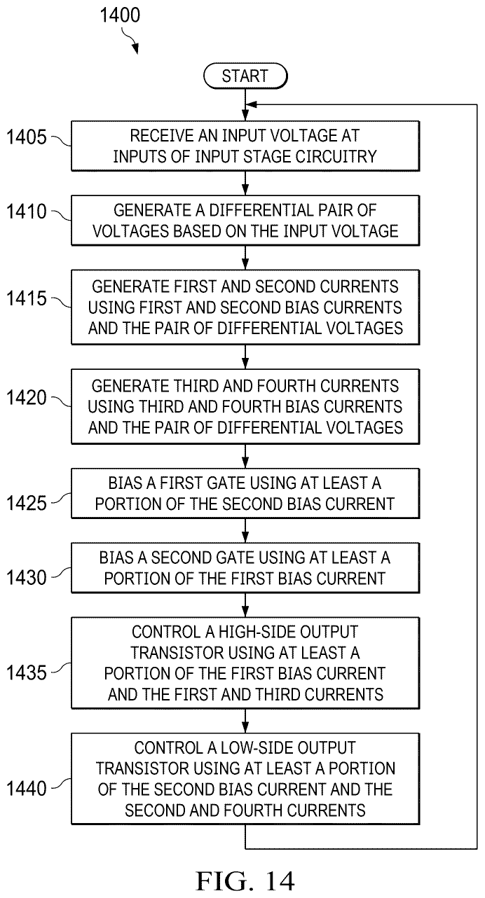

In example operations, the input stage 110 receives the inverting and non-inverting input signals. The input stage 110 sets the first and second inputs of the amplifier circuitry as high impedance inputs and produces inverting and non-inverting opposed-buffer stage input voltages based on the difference between the voltages of the inverting and non-inverting input signals. In some examples, such as the examples of FIGS. 6, 10, 11, 12, and 13, the input stage 110 produces a single ended output voltage based on the inverting and non-inverting input signals. The opposed-buffer stage 120 converts the inverting and non-inverting opposed-buffer stage input voltages to source and sink currents. The opposed-buffer stage 120 supplies the source and sink currents to the output stage 130. In some examples, the opposed-buffer stage 120 further sources or sinks bias currents to/from the output stage 130. The output stage 130 sets the output of the amplifier circuitry 100 responsive to the source and sink currents of the opposed-buffer stage 120. Further example operations of the amplifier circuitry 100 are further illustrated and discussed in connection with FIGS. 8 and 14.

FIG. 2 is a schematic diagram of amplifier circuitry 200 including an example opposed-buffer stage 205, which is an example of the opposed-buffer stage 120 of FIG. 1, an example output stage 210, which is an example of the output stage 130 of FIG. 1, and example control signal generation circuitry 215. The example opposed-buffer stage 205 of FIG. 2 includes first example buffer circuitry 220, an example resistor 225, second example buffer circuitry 230, third example buffer circuitry 235, and example switch circuitry 240. The example output stage 210 of FIG. 2 includes first example current mirror circuitry 245, second example current mirror circuitry 250, example class AB control circuitry 255, first example switch circuitry 260, second example switch circuitry 265, a first example transistor 270, and a second example transistor 275.

The amplifier circuitry 200 has a first input, a second input, and an output. The first input of the amplifier circuitry 200 is structured to be coupled to the input stage 110 of FIG. 1, which supplies an inverting input voltage (V_{IN_STAGE-}). The second input of the amplifier circuitry 200 is structured to be coupled to the input stage 110, which supplies a non-inverting input voltage (V_{IN_STAGE+}). In some examples, the second input of the amplifier circuitry 200 is structured to be coupled to a reference input, which supplies a reference voltage (V_{REF}). The output of the amplifier circuitry 200 is structured to be coupled to downstream circuitry, which receives an output voltage (V_{OUT}). In the example of FIG. 2, the amplifier circuitry 200 includes the opposed-buffer stage 205 and the output stage 210. However, in some examples the amplifier circuitry 200 includes an additional stage, such as the input stage 110 of FIG. 1.

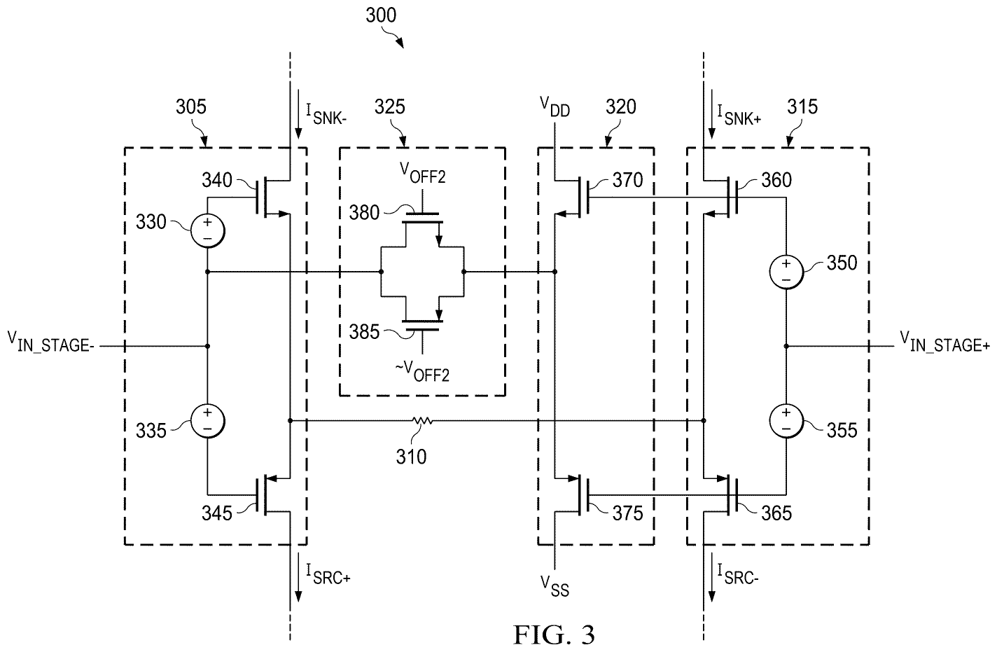

The opposed-buffer stage 205 has a first terminal, a second terminal, a third terminal, a fourth terminal, a fifth terminal, a sixth terminal, and a seventh terminal. The first terminal of the opposed-buffer stage 205 is coupled to the first input of the amplifier circuitry 200, which supplies the inverting input voltage. The second terminal of the opposed-buffer stage 205 is coupled to the second input of the amplifier circuitry 200, which supplies the non-inverting input voltage. The third terminal of the opposed-buffer stage 205 is coupled to the control signal generation circuitry 215. The fourth, fifth, sixth, and seventh terminals of the opposed-buffer stage 205 are coupled to the output stage 210. Additional examples of the opposed-buffer stage 205 are further illustrated and described in connection with FIGS. 3, 4, 5, 6, 10, 11, 12, and 13.

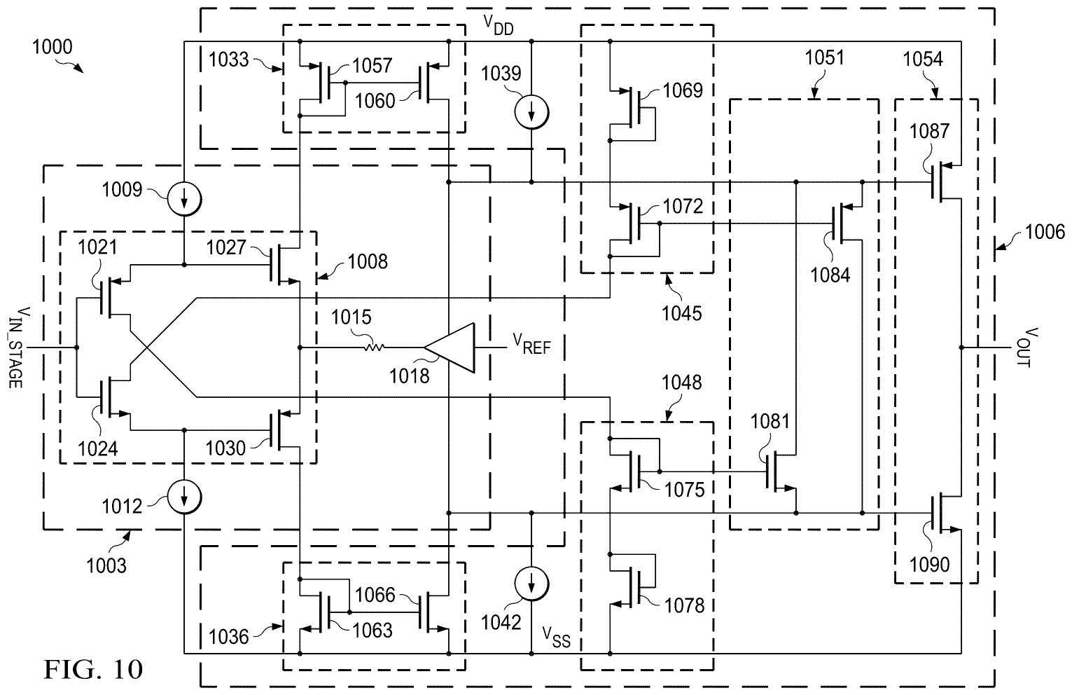

The output stage 210 (also referred to as a Monticelli output stage) has a first terminal, a second terminal, a third terminal, a fourth terminal, a fifth terminal, a sixth terminal, and a seventh terminal. The first, second, third, and fourth terminals of the output stage 210 are coupled to the opposed-buffer stage 205. The fifth and sixth terminals of the output stage 210 are coupled to the control signal generation circuitry 215. The seventh terminal of the output stage 210 is coupled to the output of the amplifier circuitry 200, which supplies the output voltage to downstream circuitry. Additional examples of the output stage 210 are further illustrated and described in connection with FIGS. 10, 11, 12, and 13.

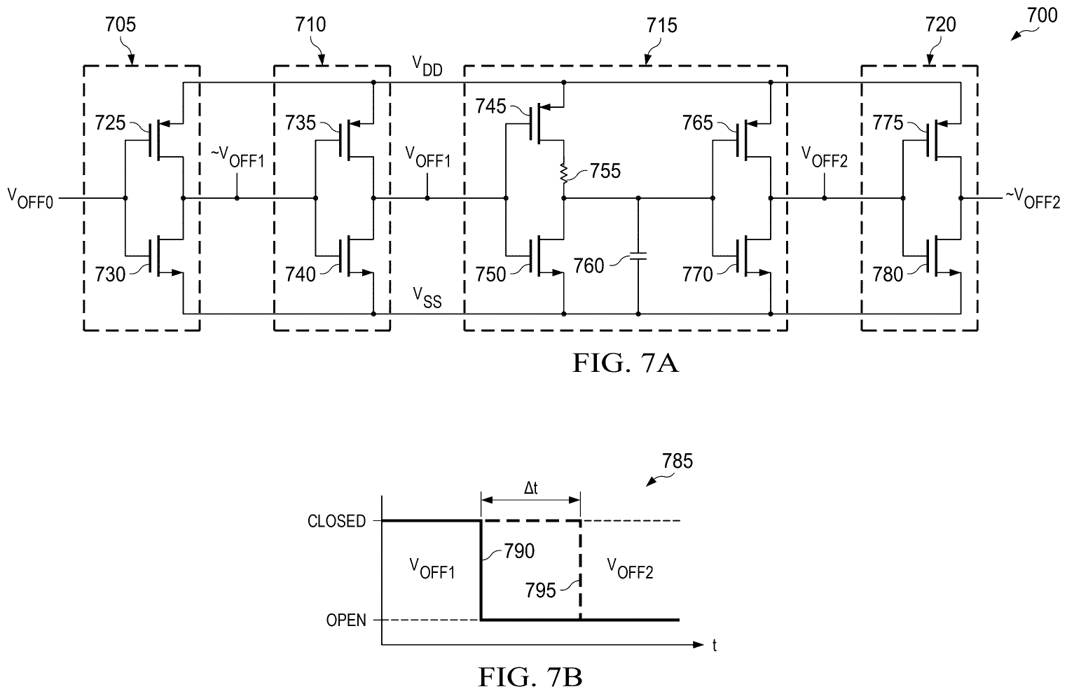

The control signal generation circuitry 215 has a first terminal, a second terminal, a third terminal, and a fourth terminal. The first and second terminals of the control signal generation circuitry 215 are coupled to the output stage 210. The third and fourth terminals of the control signal generation circuitry 215 are coupled to the opposed-buffer stage 205. An example of the control signal generation circuitry 215 is further illustrated and described in connection with FIG. 7A.

The buffer circuitry 220 has a first terminal, a second terminal, a third terminal, and a fourth terminal. The first terminal of the buffer circuitry 220 is coupled to the switch circuitry 240 and the first input of the amplifier circuitry 200, which supplies the inverting input voltage. The second terminal of the buffer circuitry 220 is coupled to the resistor 225. The third terminal of the buffer circuitry 220 is coupled to the current mirror circuitry 245. The fourth terminal of the buffer circuitry 220 is coupled to the current mirror circuitry 250. Examples of the buffer circuitry 220 are further illustrated and described in connection with FIGS. 3, 4, 5, 6, 10, 11, 12, and 13.

The resistor 225 has a first terminal and a second terminal. The first terminal of the resistor 225 is coupled to the buffer circuitry 220. The second terminal of the resistor 225 is coupled to the buffer circuitry 230.

The buffer circuitry 230 has a first terminal, a second terminal, a third terminal, and a fourth terminal. The first terminal of the buffer circuitry 230 is coupled to the buffer circuitry 235 and the second input of the amplifier circuitry 200, which supplies the non-inverting input voltage. The second terminal of the buffer circuitry 230 is coupled to the resistor 225. The third terminal of the buffer circuitry 230 is coupled to the current mirror circuitry 245, the class AB control circuitry 255, the switch circuitry 260, and the transistor 270. The fourth terminal of the buffer circuitry 230 is coupled to the current mirror circuitry 250, the class AB control circuitry 255, the switch circuitry 265, and the transistor 275. Examples of the buffer circuitry 230 are further illustrated and described in connection with FIGS. 3, 4, 5, 6, 10, 11, 12, and 13.

The buffer circuitry 235 has a first terminal and a second terminal. The first terminal of the buffer circuitry 235 is coupled to the buffer circuitry 230 and the second input of the amplifier circuitry 200, which supplies the non-inverting input voltage. The second terminal of the buffer circuitry 235 is coupled to the switch circuitry 240. Examples of the buffer circuitry 235 are further illustrated and described in connection with FIGS. 3, 4, 5, and 6.

The switch circuitry 240 has a first terminal, a second terminal, a first control terminal, and a second control terminal. The first terminal of the switch circuitry 240 is coupled to the buffer circuitry 235. The second terminal of the switch circuitry 240 is coupled to the buffer circuitry 220 and the first input of the amplifier circuitry 200, which supplies the inverting input voltage. The first and second control terminals of the switch circuitry 240 are coupled to the control signal generation circuitry 215, which supplies a second control signal (V_{OFF2}) and a second inverted control signal (˜V_{OFF2}). Examples of the switch circuitry 240 are further illustrated and described in connection with FIGS. 3, 4, 5, and 6.

The current mirror circuitry 245 has a first terminal, a second terminal, and a third terminal. The first terminal of the current mirror circuitry 245 is coupled to the buffer circuitry 220. The second terminal of the current mirror circuitry 245 is coupled to the buffer circuitry 230, the class AB control circuitry 255, the switch circuitry 260, and the transistor 270. The third terminal of the current mirror circuitry 245 is coupled to a supply terminal, which supplies a supply voltage (V_{DD}). Examples of the current mirror circuitry 245 are further illustrated and described in connection with FIGS. 10, 11, 12, and 13.

The current mirror circuitry 250 has a first terminal, a second terminal, and a third terminal. The first terminal of the current mirror circuitry 250 is coupled to the buffer circuitry 220. The second terminal of the current mirror circuitry 250 is coupled to the buffer circuitry 230, the class AB control circuitry 255, the switch circuitry 265, and the transistor 275. The third terminal of the current mirror circuitry 250 is coupled to a common terminal, which supplies a common voltage (e.g., ground, AVSS, V_{SS}). Examples of the current mirror circuitry 250 are further illustrated and described in connection with FIGS. 10, 11, 12, and 13.

The class AB control circuitry 255 has a first terminal and a second terminal. The first terminal of the class AB control circuitry 255 is coupled to the buffer circuitry 230, the current mirror circuitry 245, the switch circuitry 260, and the transistor 270. The second terminal of the class AB control circuitry 255 is coupled to the buffer circuitry 230, the current mirror circuitry 250, the switch circuitry 265, and the transistor 275. An example of the class AB control circuitry 255 is further illustrated and described in connection with FIGS. 10, 11, 12, and 13.

The switch circuitry 260 has a first terminal, a second terminal, and a control terminal. The first terminal of the switch circuitry 260 is coupled to the supply terminal, which supplies the supply voltage. The second terminal of the switch circuitry 260 is coupled to the buffer circuitry 230, the current mirror circuitry 245, the class AB control circuitry 255, and the transistor 270. The control terminal of the switch circuitry 260 is coupled to the control signal generation circuitry 215, which supplies a first inverted control signal (˜V_{OFF1}).

The switch circuitry 265 has a first terminal, a second terminal, and a control terminal. The first terminal of the switch circuitry 265 is coupled to the buffer circuitry 230, the current mirror circuitry 250, the class AB control circuitry 255, and the transistor 275. The second terminal of the switch circuitry 265 is coupled to the common terminal, which supplies the common potential. The control terminal of the switch circuitry 265 is coupled to the control signal generation circuitry 215, which supplies a first control signal (V_{OFF1}). In the example of FIG. 2, the inverted control signal is an inverted (or one-hundred-and-eighty-degree phase shifted) version of the first control signal. In such examples, the first control signal and the inverted control signal synchronize turning on and off the switch circuitry 260, 265.

The transistor 270 has a first terminal, a second terminal, and a control terminal. The first terminal of the transistor 270 is coupled to the supply terminal, which supplies the supply voltage. The second terminal of the transistor 270 is coupled to the transistor 275 and the output of the amplifier circuitry 200, which supplies the output voltage to downstream circuitry. The control terminal of the transistor 270 is coupled to the buffer circuitry 230, the current mirror circuitry 245, the class AB control circuitry 255, and the switch circuitry 260.

The transistor 275 has a first terminal, a second terminal, and a control terminal. The first terminal of the transistor 275 is coupled to the transistor 270 and the output of the amplifier circuitry 200, which supplies the output voltage to downstream circuitry. The second terminal of the transistor 275 is coupled to the common terminal, which supplies the common potential. The control terminal of the transistor 275 is coupled to the buffer circuitry 230, the current mirror circuitry 250, the class AB control circuitry 255, and the switch circuitry 265.

In the example of FIG. 2, the transistor 275 is an n-channel metal-oxide semiconductor field-effect transistor (MOSFET). Alternatively, the transistor 275 may be an n-channel field-effect transistor (FET), an n-channel insulated-gate bipolar transistor (IGBT), an n-channel junction field effect transistor (JFET), a NPN bipolar junction transistor (BJT) or, with slight modifications, a p-type equivalent device. In the example of FIG. 2, the transistor 270 is a p-channel MOSFET. Alternatively, the transistor 270 may be a p-channel FET, a p-channel IGBT, a p-channel JFET, a PNP BJT, or, with slight modifications, an n-type equivalent device. The transistors 270, 275 may be depletion mode devices, drain-extended devices, enhancement mode devices, natural transistors or other type of device structure transistors. Furthermore, the transistors 270, 275 may be implemented in/over a silicon substrate (Si), a silicon carbide substrate (SiC), a gallium nitride substrate (GaN) or a gallium arsenide substrate (GaAs).

FIG. 3 is a schematic diagram of an example opposed-buffer stage 300, which is an example of the opposed-buffer stages 120, 205 of FIGS. 1 and 2. In the example of FIG. 3, the opposed-buffer stage 300 includes first buffer circuitry 305, a resistor 310, second buffer circuitry 315, third buffer circuitry 320, and switch circuitry 325. The example buffer circuitry 305 of FIG. 3 includes first example voltage source circuitry 330, second example voltage source circuitry 335, a first example transistor 340, and a second example transistor 345. The example buffer circuitry 315 of FIG. 3 includes first example voltage source circuitry 350, second example voltage source circuitry 355, a first example transistor 360, and a second example transistor 365. The example buffer circuitry 320 of FIG. 3 includes a first example transistor 370 and a second example transistor 375. The example switch circuitry 325 of FIG. 3 includes a first example transistor 380 and a second example transistor 385.

The opposed-buffer stage 300 has a first input, a second input, a third input, a fourth input, a first output, a second output, a third output, and a fourth output. The first input of the opposed-buffer stage 300 is structured to be coupled to the input stage 110 of FIG. 1, which supplies an inverting input voltage (V_{IN_STAGE-}). The second input of the opposed-buffer stage 300 is structured to be coupled to the input stage 110, which supplies a non-inverting input voltage (V_{IN_STAGE+}). In some examples, the second input of the opposed-buffer stage 300 is structured to be coupled to a reference input, which supplies a reference voltage (V_{REF}). The third input of the opposed-buffer stage 300 is structured to be coupled to the control signal generation circuitry 215 of FIG. 2, which supplies the second control signal (V_{OFF2}). The fourth input of the opposed-buffer stage 300 is structured to be coupled to the control signal generation circuitry 215, which supplies a second inverted control signal (˜V_{OFF2}). In the example of FIG. 3, the second inverted control signal is an inverted version of the second control signal. The first output of the opposed-buffer stage 300 is structured to be coupled to the output stages 130, 210 of FIGS. 1 and 2, which supplies an inverting sink current (I_{SNK-}). The second output of the opposed-buffer stage 300 is structured to be coupled to the output stages 130, 210, which receives a non-inverting source current (I_{SRC+}). The third output of the opposed-buffer stage 300 is structured to be coupled to the output stages 130, 210, which supplies a non-inverting sink current (I_{SNK+}). The fourth output of the opposed-buffer stage 300 is structured to be coupled to the output stages 130, 210, which receives an inverting source current (I_{SRC-}).

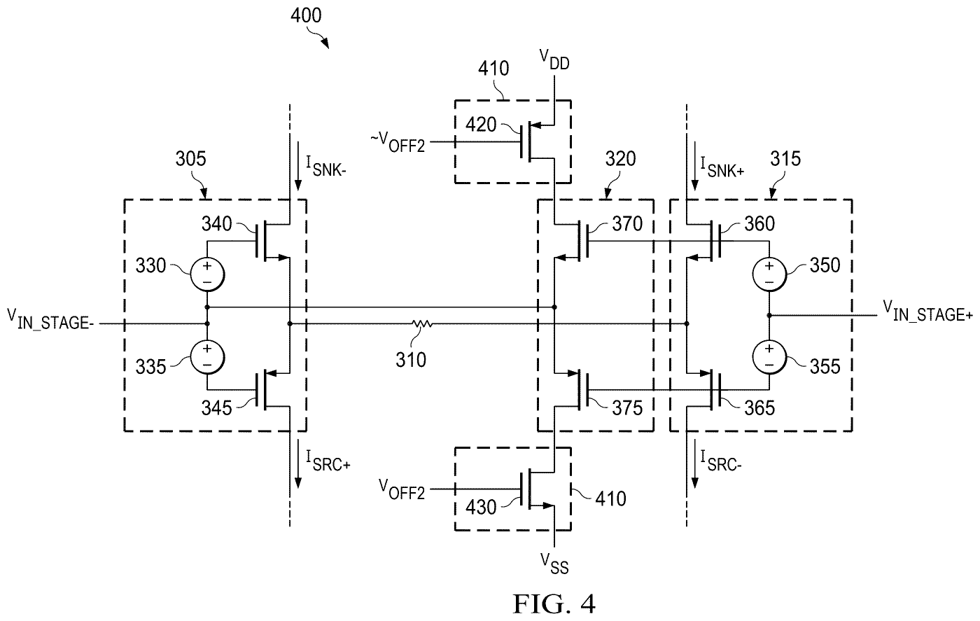

The buffer circuitry 305 has a first terminal, a second terminal, a third terminal, and a fourth terminal. The first terminal of the buffer circuitry 305 is coupled to the switch circuitry 325 and the first input of the opposed-buffer stage 300, which supplies the inverting input voltage. The second terminal of the buffer circuitry 305 is coupled to the resistor 310. The third terminal of the buffer circuitry 305 is coupled to the first output of the opposed-buffer stage 300, which supplies the inverting sink current. The fourth terminal of the buffer circuitry 305 is coupled to the second output of the opposed-buffer stage 300, which supplies the non-inverting source current. The buffer circuitry 305 is an example of the buffer circuitry 220 of FIG. 2. Other examples of the buffer circuitry 305 are further illustrated and described in connection with FIGS. 4, 5, 6, 10, 11, 12, and 13.

The resistor 310 has a first terminal and a second terminal. The first terminal of the resistor 310 is coupled to the buffer circuitry 305. The second terminal of the resistor 310 is coupled to the buffer circuitry 315. The resistor 310 is an example of the resistor 225 of FIG. 2.

The buffer circuitry 315 has a first terminal, a second terminal, a third terminal, a fourth terminal, a fifth terminal, and a sixth terminal. The first terminal of the buffer circuitry 315 is coupled to the second input of the opposed-buffer stage 300, which supplies the non-inverting input voltage (V_{IN_STAGE+}). The second terminal of the buffer circuitry 315 is coupled to the resistor 310. The third and fourth terminals of the buffer circuitry 315 are coupled to the buffer circuitry 320. The fifth terminal of the buffer circuitry 315 is coupled to the third output of the opposed-buffer stage 300, which supplies the non-inverting sink current. The sixth terminal of the buffer circuitry 315 is coupled to the fourth output of the opposed-buffer stage 300, which supplies the inverting source current. The buffer circuitry 315 is an example of the buffer circuitry 230 of FIG. 2. Other examples of the buffer circuitry 315 are further illustrated and described in connection with FIGS. 4, 5, 6, 10, 11, 12, and 13.

The buffer circuitry 320 has a first terminal, a second terminal, a third terminal, a fourth terminal, and a fifth terminal. The first and second terminals of the buffer circuitry 320 are coupled to the buffer circuitry 315. The third terminal of the buffer circuitry 320 is coupled to the switch circuitry 325. The fourth terminal of the buffer circuitry 320 is coupled to the supply terminal, which supplies the supply voltage. The fifth terminal of the buffer circuitry 320 is coupled to the common terminal, which supplies the common potential. The buffer circuitry 320 is an example of the buffer circuitry 235 of FIG. 2. Other examples of the buffer circuitry 320 are further illustrated and described in connection with FIGS. 4, 5, and 6.

The switch circuitry 325 has a first terminal, a second terminal, a third terminal, and a fourth terminal. The first terminal of the switch circuitry 325 is coupled to the buffer circuitry 320. The second terminal of the switch circuitry 325 is coupled to the buffer circuitry 305 and the first input of the opposed-buffer stage 300, which supplies the inverting input voltage. The third terminal of the switch circuitry 325 is coupled to the third input of the opposed-buffer stage 300, which supplies the second control signal. The fourth terminal of the switch circuitry 325 is coupled to the fourth input of the opposed-buffer stage 300, which supplies the second inverted control signal. In some examples, the switch circuitry 325 is referred to as a transmission gate. The switch circuitry 325 is an example of the switch circuitry 240 of FIG. 2. Other examples of the switch circuitry 325 are further illustrated and described in connection with FIGS. 4, 5, and 6.

The voltage source circuitry 330 has a first terminal and a second terminal. The first terminal of the voltage source circuitry 330 is coupled to the transistor 340. The second terminal of the voltage source circuitry 330 is coupled to the voltage source circuitry 335, the transistors 380, 385, and the first input of the opposed-buffer stage 300, which supplies the inverting input voltage.

The voltage source circuitry 335 has a first terminal and a second terminal. The first terminal of the voltage source circuitry 335 is coupled to the voltage source circuitry 330, the transistors 380, 385, and the first input of the opposed-buffer stage 300, which supplies the inverting input voltage. The second terminal of the voltage source circuitry 335 is coupled to the transistor 345. In some examples, the voltage source circuitry 330, 335 are implemented using transistor(s) and bias current source circuitry. Such examples are further illustrated and described in connection with FIGS. 6, 10, 11, 12, and 13.

The transistor 340 has a first terminal, a second terminal, and a control terminal. The first terminal of the transistor 340 is coupled to the first output of the opposed-buffer stage 300, which sinks the inverting sink current. The second terminal of the transistor 340 is coupled to the resistor 310 and the transistor 345. The control terminal of the transistor 340 is coupled to the voltage source circuitry 330.

The transistor 345 has a first terminal, a second terminal, and a control terminal. The first terminal of the transistor 345 is coupled to the resistor 310 and the transistor 340. The second terminal of the transistor 345 is coupled to the second output of the opposed-buffer stage 300, which supplies the non-inverting source current. The control terminal of the transistor 345 is coupled to the voltage source circuitry 335.

The voltage source circuitry 350 has a first terminal and a second terminal. The first terminal of the voltage source circuitry 350 is coupled to the transistors 360, 370. The second terminal of the voltage source circuitry 350 is coupled to the voltage source circuitry 355 and the second input of the opposed-buffer stage 300, which supplies the non-inverting input voltage.

The voltage source circuitry 355 has a first terminal and a second terminal. The first terminal of the voltage source circuitry 355 is coupled to the voltage source circuitry 350 and the second input of the opposed-buffer stage 300, which supplies the non-inverting input voltage. The second terminal of the voltage source circuitry 355 is coupled to the transistor 365, 375. In some examples, the voltage source circuitry 350, 355 are implemented using transistor(s) and bias current source circuitry. Such examples are further illustrated and described in connection with FIGS. 6, 10, 11, 12, and 13.

The transistor 360 has a first terminal, a second terminal, and a control terminal. The first terminal of the transistor 360 is coupled to the third output of the opposed-buffer stage 300, which sinks the non-inverting sink current. The second terminal of the transistor 360 is coupled to the resistor 310 and the transistor 365. The control terminal of the transistor 360 is coupled to the voltage source circuitry 350 and the transistor 370.

The transistor 365 has a first terminal, a second terminal, and a control terminal. The first terminal of the transistor 365 is coupled to the resistor 310 and the transistor 360. The second terminal of the transistor 365 is coupled to the fourth output of the opposed-buffer stage 300, which supplies the inverting source current. The control terminal of the transistor 365 is coupled to the voltage source circuitry 355 and the transistor 375.

The transistor 370 has a first terminal, a second terminal, and a control terminal. The first terminal of the transistor 370 is coupled to the supply terminal, which supplies the supply voltage. The second terminal of the transistor 370 is coupled to the transistors 375, 380, 385. The control terminal of the transistor 370 is coupled to the voltage source circuitry 350 and the transistor 360.

The transistor 375 has a first terminal, a second terminal, and a control terminal. The first terminal of the transistor 375 is coupled to the transistors 370, 380, 385. The second terminal of the transistor 375 is coupled to the common terminal, which supplies the common potential. The control terminal of the transistor 375 is coupled to the voltage source circuitry 355 and the transistor 365.

The transistor 380 has a first terminal, a second terminal, and a control terminal. The first terminal of the transistor 380 is coupled to the voltage source circuitry 330, 335, the transistor 385, and the first input of the opposed-buffer stage 300, which supplies the inverting input voltage. The second terminal of the transistor 380 is coupled to the transistors 370, 375, 385. The control terminal of the transistor 380 is coupled to the third input of the opposed-buffer stage 300, which supplies the second control signal.

The transistor 385 has a first terminal, a second terminal, and a control terminal. The first terminal of the transistor 385 is coupled to the voltage source circuitry 330, 335, the transistor 380, and the first input of the opposed-buffer stage 300, which supplies the inverting input voltage. The second terminal of the transistor 385 is coupled to the transistors 370, 375, 380. The control terminal of the transistor 385 is coupled to the fourth input of the opposed-buffer stage 300, which supplies the second inverted control signal.

In the example of FIG. 3, the transistors 340, 360, 370, 380 are n-channel MOSFETs. Alternatively, the transistors 340, 360, 370, 380 may be n-channel FETs, n-channel IGBTs, n-channel JFETs, NPN BJTs or, with slight modifications, p-type equivalent devices. In the example of FIG. 3, the transistors 345, 365, 375, 385 are p-channel MOSFETs. Alternatively, the transistors 345, 365, 375, 385 may be p-channel FETs, p-channel IGBTs, p-channel JFETs, PNP BJTs, or, with slight modifications, N-type equivalent devices. The transistors 340, 345, 360, 365, 370, 375, 380, 385 may be depletion mode devices, drain-extended devices, enhancement mode devices, natural transistors or other type of device structure transistors. Furthermore, the transistors 340, 345, 360, 365, 370, 375, 380, 385 may be implemented in/over a silicon substrate (Si), a silicon carbide substrate (SiC), a gallium nitride substrate (GaN) or a gallium arsenide substrate (GaAs).

FIG. 4 is a schematic diagram of an example opposed-buffer stage 400, which is another example of the opposed-buffer stages 120, 205, 300 of FIGS. 1, 2, and 3. In the example of FIG. 4, the opposed-buffer stage 400 includes the buffer circuitry 305, 315, 320 of FIG. 3, the resistor 310 of FIG. 3, and switch circuitry 410. The example buffer circuitry 305 of FIG. 4 includes the voltage source circuitry 330, 335 of FIG. 3 and the transistors 340, 345 of FIG. 3. The example buffer circuitry 315 of FIG. 4 includes the voltage source circuitry 350, 355 of FIG. 3 and the transistors 360, 365 of FIG. 3. The example buffer circuitry 320 of FIG. 4 includes the transistor 370, 375 of FIG. 3. The example switch circuitry 410 of FIG. 4 includes a first example transistor 420 and a second example transistor 430.

The opposed-buffer stage 400 has a first input, a second input, a third input, a fourth input, a first output, a second output, a third output, and a fourth output. The first input of the opposed-buffer stage 400 is structured to be coupled to the input stage 110 of FIG. 1, which supplies an inverting input voltage (V_{IN_STAGE-}). The second input of the opposed-buffer stage 400 is structured to be coupled to the input stage 110, which supplies a non-inverting input voltage (V_{IN_STAGE+}). In some examples, the second input of the opposed-buffer stage 400 is structured to be coupled to a reference input, which supplies a reference voltage (V_{REF}). The third input of the opposed-buffer stage 400 is structured to be coupled to the control signal generation circuitry 215 of FIG. 2, which supplies the second control signal (V_{OFF2}). The fourth input of the opposed-buffer stage 400 is structured to be coupled to the control signal generation circuitry 215, which supplies the second inverted control signal (˜V_{OFF2}). The first output of the opposed-buffer stage 400 is structured to be coupled to the output stages 130, 210 of FIGS. 1 and 2, which supplies an inverting sink current (I_{SNK-}). The second output of the opposed-buffer stage 400 is structured to be coupled to the output stages 130, 210, which receive a non-inverting source current (I_{SRC+}). The third output of the opposed-buffer stage 400 is structured to be coupled to the output stages 130, 210, which supplies a non-inverting sink current (I_{SNK+}). The fourth output of the opposed-buffer stage 400 is structured to be coupled to the output stages 130, 210, which receive an inverting source current (I_{SRC-}).

In the example of FIG. 4, the buffer circuitry 320 has a first terminal, a second terminal, a third terminal, a fourth terminal, and a fifth terminal. The first and second terminals of the buffer circuitry 320 are coupled to the buffer circuitry 315. The third terminal of the buffer circuitry 320 is coupled to the voltage source circuitry 330, 335, or more generally the buffer circuitry 305, and the first input of the opposed-buffer stage 400, which supplies the inverting input voltage. The fourth and fifth terminals of the buffer circuitry 320 are coupled to the switch circuitry 410.

The switch circuitry 410 has a first terminal, a second terminal, a third terminal, a fourth terminal, a fifth terminal, and a sixth terminal. The first terminal of the switch circuitry 410 is coupled to the supply terminal, which supplies the supply voltage. The second terminal of the switch circuitry 410 is coupled to the third input of the opposed-buffer stage 400, which supplies the second control signal. The third and fourth terminals of the switch circuitry 410 are coupled to the buffer circuitry 320. The fifth terminal of the switch circuitry 410 is coupled to the fourth input of the opposed-buffer stage 400, which supplies the second inverted control signal. The sixth terminal of the switch circuitry 410 is coupled to the common terminal, which supplies the common voltage. The switch circuitry 410 is an example of an alternative placement of the switch circuitry 240, 325.

Unlike in the example of FIG. 3, the switch circuitry 410 controls the supply of current to the transistors 370, 375, or more generally the buffer circuitry 320. Advantageously, such a positioning of the switch circuitry 410 reduces an impedance between the buffer circuitry 305, 320 when the switch circuitry 410 is closed. Advantageously, reducing the impedance between the buffer circuitry 305, 320 increases a drive strength of the output of the buffer circuitry 320 at the input of the buffer circuitry 305. Advantageously, the switch circuitry 410 reduces the power consumption of the buffer circuitry 320 during normal operation of the amplifier circuitry 100 responsive to preventing a supply of power to the transistors 370, 375.

The transistor 420 has a first terminal, a second terminal, and a control terminal. The first terminal of the transistor 420 is coupled to the supply terminal, which supplies the supply voltage. The second terminal of the transistor 420 is coupled to the transistor 370. The control terminal of the transistor 420 is coupled to the fourth input of the opposed-buffer stage 400, which supplies the second inverted control signal.

The transistor 430 has a first terminal, a second terminal, and a control terminal. The first terminal of the transistor 430 is coupled to the transistor 375. The second terminal of the transistor 430 is coupled to the common terminal, which supplies the common voltage. The control terminal of the transistor 430 is coupled to the third input of the opposed-buffer stage 400, which supplies the second control signal.

In the example of FIG. 4, the transistors 340, 360, 370, 430 are n-channel MOSFETs. Alternatively, the transistors 340, 360, 370, 430 may be n-channel FETs, n-channel IGBTs, n-channel JFETs, NPN BJTs or, with slight modifications, p-type equivalent devices. In the example of FIG. 4, the transistors 345, 365, 375, 420 are p-channel MOSFETs. Alternatively, the transistors 345, 365, 375, 420 may be p-channel FETs, p-channel IGBTs, p-channel JFETs, PNP BJTs, or, with slight modifications, N-type equivalent devices. The transistors 340, 345, 360, 365, 370, 375, 420, 430 may be depletion mode devices, drain-extended devices, enhancement mode devices, natural transistors or other type of device structure transistors. Furthermore, the transistors 340, 345, 360, 365, 370, 375, 420, 430 may be implemented in/over a silicon substrate (Si), a silicon carbide substrate (SiC), a gallium nitride substrate (GaN) or a gallium arsenide substrate (GaAs).

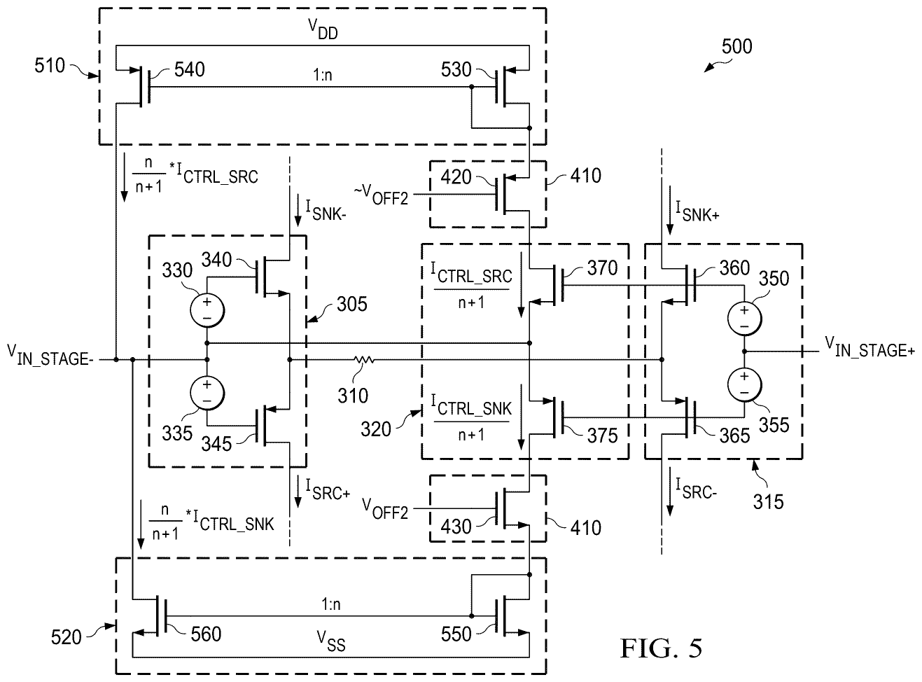

FIG. 5 is a schematic diagram of an example opposed-buffer stage 500, which is another example of the opposed-buffer stages 120, 205, 300, 400 of FIGS. 1, 2, 3, and 4. In the example of FIG. 5, the opposed-buffer stage 500 includes the buffer circuitry 305, 315, 320 of FIGS. 3 and 4, the resistor 310 of FIGS. 3 and 4, the switch circuitry 410 of FIG. 4, first current mirror circuitry 510, and second current mirror circuitry 520. The example buffer circuitry 305 of FIG. 5 includes the voltage source circuitry 330, 335 of FIGS. 3 and 4 and the transistors 340, 345 of FIGS. 3 and 4. The example buffer circuitry 315 of FIG. 5 includes the voltage source circuitry 350, 355 of FIGS. 3 and 4 and the transistors 360, 365 of FIGS. 3 and 4. The example buffer circuitry 320 of FIG. 5 includes the transistor 370, 375 of FIGS. 3 and 4. The example switch circuitry 410 of FIG. 5 includes the transistors 420, 430 of FIG. 4. The example current mirror circuitry 510 of FIG. 5 includes a first example transistor 530 and a second example transistor 540. The example current mirror circuitry 520 of FIG. 5 includes a first example transistor 550 and a second example transistor 560.

The opposed-buffer stage 500 has a first input, a second input, a third input, a fourth input, a first output, a second output, a third output, and a fourth output. The first input of the opposed-buffer stage 500 is structured to be coupled to the input stage 110 of FIG. 1, which supplies an inverting input voltage (V_{IN_STAGE-}). The second input of the opposed-buffer stage 500 is structured to be coupled to the input stage 110, which supplies a non-inverting input voltage (V_{IN_STAGE+}). In some examples, the second input of the opposed-buffer stage 500 is structured to be coupled to a reference input, which supplies a reference voltage (V_{REF}). The third input of the opposed-buffer stage 500 is structured to be coupled to the control signal generation circuitry 215 of FIG. 2, which supplies the second control signal (V_{OFF2}). The fourth input of the opposed-buffer stage 500 is structured to be coupled to the control signal generation circuitry 215, which supplies the second inverted control signal (˜V_{OFF2}). The first output of the opposed-buffer stage 500 is structured to be coupled to the output stages 130, 210 of FIGS. 1 and 2, which supplies an inverting sink current (I_{SNK-}). The second output of the opposed-buffer stage 500 is structured to be coupled to the output stages 130, 210, which receive a non-inverting source current (I_{SRC+}). The third output of the opposed-buffer stage 500 is structured to be coupled to the output stages 130, 210, which supplies a non-inverting sink current (I_{SNK+}). The fourth output of the opposed-buffer stage 500 is structured to be coupled to the output stages 130, 210, which receive an inverting source current (I_{SRC-}).

In the example of FIG. 5, the switch circuitry 410 has a first terminal, a second terminal, a third terminal, a fourth terminal, a fifth terminal, and a sixth terminal. The first terminal of the switch circuitry 410 is coupled to the current mirror circuitry 510. The second terminal of the switch circuitry 410 is coupled to the third input of the opposed-buffer stage 400, which supplies the second control signal. The third and fourth terminals of the switch circuitry 410 are coupled to the buffer circuitry 320. The fifth terminal of the switch circuitry 410 is coupled to the fourth input of the opposed-buffer stage 400, which supplies the second inverted control signal. The sixth terminal of the switch circuitry 410 is coupled to the current mirror circuitry 520.

The current mirror circuitry 510 has a first terminal, a second terminal, and a third terminal. The first terminal of the current mirror circuitry 510 is coupled to the switch circuitry 410. The second terminal of the current mirror circuitry 510 is coupled to the buffer circuitry 305, 320, the current mirror circuitry 520, and the first input of the opposed-buffer stage 500, which supplies the inverting input voltage. The third terminal of the current mirror circuitry 510 is coupled to the supply terminal, which supplies the supply voltage.

The current mirror circuitry 520 has a first terminal, a second terminal, and a third terminal. The first terminal of the current mirror circuitry 520 is coupled to the switch circuitry 410. The second terminal of the current mirror circuitry 520 is coupled to the buffer circuitry 305, 320, the current mirror circuitry 510, and the first input of the opposed-buffer stage 500, which supplies the inverting input voltage. The third terminal of the current mirror circuitry 520 is coupled to the common terminal, which supplies the common potential.

The transistor 530 has a first terminal, a second terminal, and a control terminal. The first terminal of the transistor 530 is coupled to the supply terminal, which supplies the supply voltage. The second and control terminals of the transistor 530 are coupled to the transistors 420, 540.

The transistor 540 has a first terminal, a second terminal, and a control terminal. The first terminal of the transistor 540 is coupled to the supply terminal, which supplies the supply voltage. The second terminal of the transistor 540 is coupled to the voltage source circuitry 330, 335, the transistors 370, 375, 560, and the first input of the opposed-buffer stage 500, which supplies the inverting input voltage. The control terminal of the transistor 540 is coupled to the transistors 420, 530.

The transistor 550 has a first terminal, a second terminal, and a control terminal. The first and control terminals of the transistor 550 are coupled to the transistors 430, 560. The second terminal of the transistor 550 is coupled to the common terminal, which supplies the common potential.

The transistor 560 has a first terminal, a second terminal, and a control terminal. The first terminal of the transistor 560 is coupled to the voltage source circuitry 330, 335, the transistors 370, 375, 540, and the first input of the opposed-buffer stage 500, which supplies the inverting input voltage. The second terminal of the transistor 560 is coupled to the common terminal, which supplies the common potential. The control terminal of the transistor 560 is coupled to the transistors 430, 550.

In the example of FIG. 5, the transistors 340, 360, 370, 430, 550, 560 are n-channel MOSFETs. Alternatively, the transistors 340, 360, 370, 430, 550, 560 may be n-channel FETs, n-channel IGBTs, n-channel JFETs, NPN BJTs or, with slight modifications, p-type equivalent devices. In the example of FIG. 5, the transistors 345, 365, 375, 420, 530, 540 are p-channel MOSFETs. Alternatively, the transistors 345, 365, 375, 420, 530, 540 may be p-channel FETs, p-channel IGBTs, p-channel JFETs, PNP BJTs, or, with slight modifications, N-type equivalent devices. The transistors 340, 345, 360, 365, 370, 375, 420, 430, 530, 540, 550, 560 may be depletion mode devices, drain-extended devices, enhancement mode devices, natural transistors or other type of device structure transistors. Furthermore, the transistors 340, 345, 360, 365, 370, 375, 420, 430, 530, 540, 550, 560 may be implemented in/over a silicon substrate (Si), a silicon carbide substrate (SiC), a gallium nitride substrate (GaN) or a gallium arsenide substrate (GaAs).

Unlike in the example of FIG. 4, both the buffer circuitry 320 and the current mirror circuitry 510, 520 are coupled to the input of the buffer circuitry 305. In the example of FIG. 5, the current mirror circuitry 510, 520 mirrors the conduction of current through the transistors 370, 375 to supply a source control current (I_{CTRL_SRC}) and sink a sink control current (I_{CTRL_SNK}). Advantageously, the additional currents from the current mirror circuitry 510, 520 and current from the transistors 370, 375 set the input of the buffer circuitry 305. Advantageously, the sizes of the transistors 370, 375 may be reduced responsive to the additional current from the current mirror circuitry 510, 520 providing additional drive strength. Advantageously, sizing the length and width of the channels of the transistors 530, 540, 550, 560 by a ratio coefficient (n) allows the current mirror circuitry 510, 520 to amplify the current of the transistors 370, 375. Advantageously, the sizes of the transistors 370, 375 may further be reduced by sizing the transistors 530, 540, 550, 560 to amplify the current through the transistors 370, 375. Advantageously, decreasing the size of the transistors 370, 375 improves the linear performance of the opposed-buffer stage 500 by reducing non-linear parasitic capacitance at the first input of the opposed-buffer stage 500.

FIG. 6 is a schematic diagram of example amplifier circuitry 600 including an example input stage 605, which is an example of the input stage 110 of FIG. 1, and an example opposed-buffer stage 610, which is an example of the opposed-buffer stage 120, 205, 300, 400, 500 of FIGS. 1, 2, 3, 4, and 5. The example input stage 605 of FIG. 6 includes example transconductance circuitry 615, first example current source circuitry 620, a first example transistor 625, first example voltage source circuitry 630, a second example transistor 635, second example voltage source circuitry 640, second example current source circuitry 645, a third example transistor 650, third example voltage source circuitry 655, a fourth example transistor 660, and fourth example voltage source circuitry 665. The example opposed-buffer stage 610 of FIG. 6 includes the resistor 310 of FIGS. 3, 4, and 5, the buffer circuitry 315 of FIGS. 3, 4, and 5, the switch circuitry 410 of FIGS. 4 and 5, the current mirror circuitry 510, 520 of FIG. 5, first example buffer circuitry 668, first example current source circuitry 672, second example current source circuitry 676, and second example buffer circuitry 680. The example buffer circuitry 315 of FIG. 6 includes the voltage source circuitry 350, 355 of FIGS. 3, 4, and 5 and the transistors 360, 365 of FIGS. 3, 4, and 5. The example switch circuitry 410 of FIG. 6 includes the transistors 420, 430 of FIGS. 4 and 5. The example current mirror circuitry 510 of FIG. 6 includes the transistors 530, 540 of FIG. 5. The example current mirror circuitry 520 of FIG. 6 includes the transistors 550, 560 of FIG. 5. The example buffer circuitry 668 of FIG. 6 includes a first example transistor 682, a second example transistor 684, a third example transistor 686, and a fourth example transistor 688. The example buffer circuitry 680 of FIG. 6 includes a first example transistor 690 and a second example transistor 692.

The amplifier circuitry 600 has a first input, a second input, a first output, a second output, a third output, and a fourth output. The first input of the amplifier circuitry 600 (also referred to as a non-inverting input) is structured to be coupled to external circuitry, which supplies a non-inverting input signal (V_{IN+}). The second input of the amplifier circuitry 600 (also referred to as an inverting input) is structured to be coupled to external circuitry, which supplies an inverting input signal (V_{IN-}). The first output of the amplifier circuitry 600 is structured to be coupled to the output stages 130, 210 of FIGS. 1 and 2, which supplies an inverting sink current (I_{SNK-}). The second output of the amplifier circuitry 600 is structured to be coupled to the output stages 130, 210, which receive a non-inverting source current (I_{SRC+}). The third output of the amplifier circuitry 600 is structured to be coupled to the output stages 130, 210, which supplies a non-inverting sink current (I_{SNK+}). The fourth output of the amplifier circuitry 600 is structured to be coupled to the output stages 130, 210, which receive an inverting source current (I_{SRC-}). In the example of FIG. 6, the amplifier circuitry 600 includes the input stage 605 and the opposed-buffer stage 610. However, in some examples the amplifier circuitry 600 includes an additional stage, such as the output stages 130, 210 of FIGS. 1 and 2.

The input stage 605 has a first terminal, a second terminal, a third terminal, a fourth terminal, and a fifth terminal. The first terminal of the input stage 605 is coupled to the first input of the amplifier circuitry 600, which supplies the non-inverting input signal. The second terminal of the input stage 605 is coupled to the second input of the amplifier circuitry 600, which supplies the inverting input signal. The third, fourth, and fifth terminals of the input stage 605 are coupled to the opposed-buffer stage 610.

The opposed-buffer stage 610 has a first terminal, a second terminal, a third terminal, a fourth terminal, a fifth terminal, a sixth terminal, a seventh terminal, and an eighth terminal. The first, second, and third terminals of the opposed-buffer stage 610 are coupled to the input stage 605. The fourth terminal of the opposed-buffer stage 610 is coupled to a reference terminal, which supplies a fixed reference voltage as the non-inverting input voltage (V_{IN_STAGE+}) of the opposed-buffer stage 610. The fifth terminal of the opposed-buffer stage 610 is coupled to the first output of the amplifier circuitry 600, which sinks the inverting sink current. The sixth terminal of the opposed-buffer stage 610 is coupled to the second output of the amplifier circuitry 600, which supplies the non-inverting source current. The seventh terminal of the opposed-buffer stage 610 is coupled to the third output of the amplifier circuitry 600, which sinks the non-inverting sink current. The eighth terminal of the opposed-buffer stage 610 is coupled to the fourth output of the amplifier circuitry 600, which supplies the inverting source current.

The transconductance circuitry 615 has a first terminal, a second terminal, a third terminal, and a fourth terminal. The first terminal of the transconductance circuitry 615 is coupled to the first input of the amplifier circuitry 600, which supplies the non-inverting input signal. The second terminal of the transconductance circuitry 615 is coupled to the second input of the amplifier circuitry 600, which supplies the inverting input signal. The third terminal of the transconductance circuitry 615 is coupled to the current source circuitry 620 and the transistor 625. The fourth terminal of the transconductance circuitry 615 is coupled to the current source circuitry 645 and the transistor 650.

The current source circuitry 620 has a first terminal and a second terminal. The first terminal of the current source circuitry 620 is coupled to the supply terminal, which supplies the supply voltage. The second terminal of the current source circuitry 620 is coupled to the transconductance circuitry 615 and the transistor 625.

The transistor 625 has a first terminal, a second terminal, and a control terminal. The first terminal of the transistor 625 is coupled to the transconductance circuitry 615 and the current source circuitry 620. The second terminal of the transistor 625 is coupled to the transistors 540, 635. The control terminal of the transistor 625 is coupled to the voltage source circuitry 630.

The voltage source circuitry 630 has a first terminal and a second terminal. The first terminal of the voltage source circuitry 630 is coupled to the supply terminal, which supplies the supply voltage. The second terminal of the voltage source circuitry 630 is coupled to the transistor 625.

The transistor 635 has a first terminal, a second terminal, and a control terminal. The first terminal of the transistor 635 is coupled to the transistors 540, 625. The second terminal of the transistor 635 is coupled to the transistors 660, 682, 684. The control terminal of the transistor 635 is coupled to the voltage source circuitry 640.

The voltage source circuitry 640 has a first terminal and a second terminal. The first terminal of the voltage source circuitry 640 is coupled to the supply terminal, which supplies the supply voltage. The second terminal of the voltage source circuitry 640 is coupled to the transistor 635.

The current source circuitry 645 has a first terminal and a second terminal. The first terminal of the current source circuitry 645 is coupled to the transconductance circuitry 615 and the transistor 650. The second terminal of the current source circuitry 645 is coupled to the common terminal, which supplies the common potential.

The transistor 650 has a first terminal, a second terminal, and a control terminal. The first terminal of the transistor 650 is coupled to the transistors 560, 660. The second terminal of the transistor 650 is coupled to the transconductance circuitry 615 and the current source circuitry 645. The control terminal of the transistor 650 is coupled to the voltage source circuitry 655.

The voltage source circuitry 655 has a first terminal and a second terminal. The first terminal of the voltage source circuitry 655 is coupled to the transistor 650. The second terminal of the voltage source circuitry 655 is coupled to the common terminal, which supplies the common potential.

The transistor 660 has a first terminal, a second terminal, and a control terminal. The first terminal of the transistor 660 is coupled to the transistors 635, 682, 684. The second terminal of the transistor 660 is coupled to the transistors 560, 650. The control terminal of the transistor 660 is coupled to the voltage source circuitry 665. In some examples, the transistors 635, 660 may referred to as injection cascode transistors or cascode circuitry.

The voltage source circuitry 665 has a first terminal and a second terminal. The first terminal of the voltage source circuitry 665 is coupled to the transistor 660. The second terminal of the voltage source circuitry 665 is coupled to the common terminal, which supplies the common potential.

The buffer circuitry 668 has a first terminal, a second terminal, a third terminal, a fourth terminal, a fifth terminal, a sixth terminal, a seventh terminal, an eighth terminal, a ninth terminal, and a tenth terminal. The first terminal of the buffer circuitry 668 is coupled to the transistors 635, 660. The second terminal of the buffer circuitry 668 is coupled to the current source circuitry 672. The third terminal of the buffer circuitry 668 is coupled to the supply terminal, which supplies the supply voltage. The fourth terminal of the buffer circuitry 668 is coupled to the first output of the amplifier circuitry 600, which sinks the inverting sink current. The fifth and sixth terminals of the buffer circuitry 668 are coupled to the buffer circuitry 680. The seventh terminal of the buffer circuitry 668 is coupled to the resistor 310. The eighth terminal of the buffer circuitry 668 is coupled to the second output of the amplifier circuitry 600, which supplies the non-inverting source current. The ninth terminal of the buffer circuitry 668 is coupled to the common terminal, which supplies the common potential. The tenth terminal of the buffer circuitry 668 is coupled to the current source circuitry 676.

The current source circuitry 672 has a first terminal and a second terminal. The first terminal of the current source circuitry 672 is coupled to the supply terminal, which supplies the supply voltage. The second terminal of the current source circuitry 672 is coupled to the transistors 682, 686, 692.

The current source circuitry 676 has a first terminal and a second terminal. The first terminal of the current source circuitry 676 is coupled to the transistors 684, 688, 690. The second terminal of the current source circuitry 676 is coupled to the common terminal, which supplies the common potential.

The buffer circuitry 680 has a first terminal, a second terminal, a third terminal, a fourth terminal, and a fifth terminal. The first terminal of the buffer circuitry 680 is coupled to the voltage source circuitry 350, 355 and the input of the opposed-buffer stage 610, which supplies the non-inverting input voltage. The second terminal of the buffer circuitry 680 is coupled to the current source circuitry 672 and the transistors 682, 686. The third terminal of the buffer circuitry 680 is coupled to the transistor 420. The fourth terminal of the buffer circuitry 680 is coupled to the current source circuitry 676 and the transistors 684, 688. The fifth terminal of the buffer circuitry 680 is coupled to the transistor 430.

The transistor 682 has a first terminal, a second terminal, and a control terminal. The first terminal of the transistor 682 is coupled to the current source circuitry 672 and the transistors 686, 692. The second terminal of the transistor 682 is coupled to the common terminal, which supplies the common potential. The control terminal of the transistor 682 is coupled to the transistors 635, 660, 684.

The transistor 684 has a first terminal, a second terminal, and a control terminal. The first terminal of the transistor 684 is coupled to the supply terminal, which supplies the supply voltage. The second terminal of the transistor 684 is coupled to the current source circuitry 676 and the transistors 688, 690. The control terminal of the transistor 684 is coupled to the transistors 635, 660, 682.

The transistor 686 has a first terminal, a second terminal, and a control terminal. The first terminal of the transistor 686 is coupled to the first output of the amplifier circuitry 600, which sinks the inverting sink current. The second terminal of the transistor 686 is coupled to the resistor 310 and the transistor 688. The control terminal of the transistor 686 is coupled to the current source circuitry 672 and the transistors 682, 692.

The transistor 688 has a first terminal, a second terminal, and a control terminal. The first terminal of the transistor 688 is coupled to the resistor 310 and the transistor 686. The second terminal of the transistor 688 is coupled to the second output of the amplifier circuitry 600, which supplies the non-inverting source current. The control terminal of the transistor 688 is coupled to the current source circuitry 676 and the transistors 684, 690.

The transistor 690 has a first terminal, a second terminal, and a control terminal. The first terminal of the transistor 690 is coupled to the transistor 420. The second terminal of the transistor 690 is coupled to the current source circuitry 676 and the transistors 684, 688. The control terminal of the transistor 690 is coupled to the voltage source circuitry 350, 355, the transistor 692, and the input of the opposed-buffer stage 610, which supplies the non-inverting input voltage.

The transistor 692 has a first terminal, a second terminal, and a control terminal. The first terminal of the transistor 692 is coupled to the current source circuitry 672 and the transistors 682, 686. The second terminal of the transistor 692 is coupled to the transistor 430. The control terminal of the transistor 692 is coupled to the voltage source circuitry 350, 355, the transistor 690, and the input of the input of the opposed-buffer stage 610, which supplies the non-inverting input voltage.

In the example of FIG. 6, the transistors 360, 430, 550, 560, 650, 660, 684, 686, 690 are n-channel MOSFETs. Alternatively, the transistors 360, 430, 550, 560, 650, 660, 684, 686, 690 may be n-channel FETs, n-channel IGBTs, n-channel JFETs, NPN BJTs or, with slight modifications, p-type equivalent devices. In the example of FIG. 6, the transistors 365, 420, 530, 540, 625, 635, 682, 688, 692 are p-channel MOSFETs. Alternatively, the transistors 365, 420, 530, 540, 625, 635, 682, 688, 692 may be p-channel FETs, p-channel IGBTs, p-channel JFETs, PNP BJTs, or, with slight modifications, N-type equivalent devices. The transistors 360, 365, 420, 430, 530, 540, 550, 560, 625, 635, 650, 660, 682, 684, 686, 688, 690, 692 may be depletion mode devices, drain-extended devices, enhancement mode devices, natural transistors or other type of device structure transistors. Furthermore, the transistors 360, 365, 420, 430, 530, 540, 550, 560, 625, 635, 650, 660, 682, 684, 686, 688, 690, 692 may be implemented in/over a silicon substrate (Si), a silicon carbide substrate (SiC), a gallium nitride substrate (GaN) or a gallium arsenide substrate (GaAs).

Unlike in the example of FIG. 5, the current mirror circuitry 510, 520 is coupled to the transistors 635, 660 of the input stage 605. In the example of FIG. 6, the transistors 635, 660 combine currents from the current mirror circuitry 510, 520 and currents from the transistors 625, 650 to set the input of the buffer circuitry 668. Advantageously, the transistors 635, 660 allow the current mirror circuitry 510, 520 to drive the input of the buffer circuitry 668 without increasing the nonlinear capacitances at the input of the buffer circuitry 668. Also unlike in the example of FIG. 5, the transistors 690, 692 of the buffer circuitry 680 are coupled between the switch circuitry 410 and the control terminals of the transistors 686, 688 of the buffer circuitry 668. In the example of FIG. 6, the transistors 682, 684 isolate the transistors 690, 692 from the input of the buffer circuitry 668. Advantageously, the transistors 682, 684 may drive the buffer circuitry 680 without adding non-linear capacitances at the input of the buffer circuitry 668. Advantageously, decreasing the non-linear capacitances at the input of the buffer circuitry 668 improves linear performance of the amplifier circuitry 600.

FIG. 7A is a schematic diagram of example control signal generation circuitry 700, which is an example of the control signal generation circuitry 215 of FIG. 2. In the example of FIG. 7A, the control signal generation circuitry 700 includes first inverter circuitry 705, second inverter circuitry 710, delay circuitry 715, and third inverter circuitry 720. The example inverter circuitry 705 of FIG. 7A includes a first example transistor 725 and a second example transistor 730. The example inverter circuitry 710 of FIG. 7A includes a first example transistor 735 and a second example transistor 740. The example delay circuitry 715 of FIG. 7 includes a first example transistor 745, a second example transistor 750, an example resistor 755, an example capacitor 760, a third example transistor 765, and a fourth example transistor 770. The example inverter circuitry 720 of FIG. 7A includes a first example transistor 775 and a second example transistor 780.

The control signal generation circuitry 700 has an input, a first output, a second output, a third output, and a fourth output. The input of the control signal generation circuitry 700 is structured to be coupled to external circuitry, which supplies a reference control signal (V_{OFF0}). The first output of the control signal generation circuitry 700 is structured to be coupled to the switch circuitry 260 of FIG. 2, which receives the first inverted control signal (˜V_{OFF1}). The second output of the control signal generation circuitry 700 is structured to be coupled to the switch circuitry 265 of FIG. 2, which receives the first control signal (V_{OFF1}). The third output of the control signal generation circuitry 700 is structured to be coupled to the switch circuitry 240 of FIG. 2 and the transistors 380, 430 of FIGS. 3, 4, 5, and 6, which receive the second control signal (V_{OFF2}). The fourth output of the control signal generation circuitry 700 is structured to be coupled to the switch circuitry 240 of FIG. 2 and the transistors 385, 420 of FIGS. 3, 4, 5, and 6, which receive the second inverted control signal (˜V_{OFF2}).

The inverter circuitry 705 has a first terminal, a second terminal, a third terminal, and a fourth terminal. The first terminal of the inverter circuitry 705 is coupled to the input of the control signal generation circuitry 700, which supplies the reference control signal. The second terminal of the inverter circuitry 705 is coupled to the inverter circuitry 710 and the first output of the control signal generation circuitry 700, which supplies the first inverted control signal. The third terminal of the inverter circuitry 705 is coupled to the supply terminal, which supplies the supply voltage. The fourth terminal of the inverter circuitry 705 is coupled to the common terminal, which supplies the common potential.

The inverter circuitry 710 has a first terminal, a second terminal, a third terminal, and a fourth terminal. The first terminal of the inverter circuitry 710 is coupled to the inverter circuitry 705 and the first output of the control signal generation circuitry 700, which supplies the first inverted control signal. The second terminal of the inverter circuitry 710 is coupled to the delay circuitry 715 and the second output of the control signal generation circuitry 700, which supplies the first control signal. The third terminal of the inverter circuitry 710 is coupled to the supply terminal, which supplies the supply voltage. The fourth terminal of the inverter circuitry 710 is coupled to the common terminal, which supplies the common potential.

The delay circuitry 715 has a first terminal, a second terminal, a third terminal, and a fourth terminal. The first terminal of the delay circuitry 715 is coupled to the inverter circuitry 710 and the second output of the control signal generation circuitry 700, which supplies the first control signal. The second terminal of the delay circuitry 715 is coupled to the inverter circuitry 720 and the third output of the control signal generation circuitry 700, which supplies the second control signal. The third terminal of the delay circuitry 715 is coupled to the supply terminal, which supplies the supply voltage. The fourth terminal of the delay circuitry 715 is coupled to the common terminal, which supplies the common potential.

The inverter circuitry 720 has a first terminal, a second terminal, a third terminal, and a fourth terminal. The first terminal of the inverter circuitry 720 is coupled to the delay circuitry 715 and the third output of the control signal generation circuitry 700, which supplies the second control signal. The second terminal of the inverter circuitry 720 is coupled to the fourth output of the control signal generation circuitry 700, which supplies the second inverted control signal. The third terminal of the inverter circuitry 720 is coupled to the supply terminal, which supplies the supply voltage. The fourth terminal of the inverter circuitry 720 is coupled to the common terminal, which supplies the common potential.

The transistor 725 has a first terminal, a second terminal, and a control terminal. The first terminal of the transistor 725 is coupled to the supply terminal, which supplies the supply voltage. The second terminal of the transistor 725 is coupled to the transistors 730, 735, 740 and the first output of the control signal generation circuitry 700, which supplies the first inverted control signal. The control terminal of the transistor 725 is coupled to the transistor 730 and the input of the control signal generation circuitry 700, which supplies the reference control signal.

The transistor 730 has a first terminal, a second terminal, and a control terminal. The first terminal of the transistor 730 is coupled to the transistors 725, 735, 740 and the first output of the control signal generation circuitry 700, which supplies the first inverted control signal. The second terminal of the transistor 730 is coupled to the common terminal, which supplies the common potential. The control terminal of the transistor 730 is coupled to the transistor 725 and the input of the control signal generation circuitry 700, which supplies the reference control signal.

The transistor 735 has a first terminal, a second terminal, and a control terminal. The first terminal of the transistor 735 is coupled to the supply terminal, which supplies the supply voltage. The second terminal of the transistor 735 is coupled to the transistors 740, 745, 750 and the second output of the control signal generation circuitry 700, which supplies the first control signal. The control terminal of the transistor 735 is coupled to the transistors 725, 730, 740 and the first output of the control signal generation circuitry 700, which supplies the first inverted control signal.

The transistor 740 has a first terminal, a second terminal, and a control terminal. The first terminal of the transistor 740 is coupled to the transistors 735, 745, 750 and the second output of the control signal generation circuitry 700, which supplies the first control signal. The second terminal of the transistor 740 is coupled to the common terminal, which supplies the common potential. The control terminal of the transistor 740 is coupled to the transistors 725, 730, 735 and the first output of the control signal generation circuitry 700, which supplies the first inverted control signal.

The transistor 745 has a first terminal, a second terminal, and a control terminal. The first terminal of the transistor 745 is coupled to the supply terminal, which supplies the supply voltage. The second terminal of the transistor 745 is coupled to the resistor 755. The control terminal of the transistor 745 is coupled to the transistors 735, 740, 750 and the second output of the control signal generation circuitry 700, which supplies the first control signal.

The transistor 750 has a first terminal, a second terminal, and a control terminal. The first terminal of the transistor 750 is coupled to the resistor 755, the capacitor 760, and the transistors 765, 770. The second terminal of the transistor 750 is coupled to the common terminal, which supplies the common potential. The control terminal of the transistor 750 is coupled to the transistors 735, 740, 745 and the second output of the control signal generation circuitry 700, which supplies the first control signal.

The resistor 755 has a first terminal and a second terminal. The first terminal of the resistor 755 is coupled to the transistor 745. The second terminal of the resistor 755 is coupled to the transistors 750, 765, 770 and the capacitor 760.

The capacitor 760 has a first terminal and a second terminal. The first terminal of the capacitor 760 is coupled to the transistors 750, 765, 770 and the resistor 755. The second terminal of the capacitor 760 is coupled to the common terminal, which supplies the common potential. In the example of FIG. 7A, the resistor 755 and the capacitor 760 are structured to have a timing constant proportional to the resistance of the resistor 755 and the capacitance of the capacitor 760.

The transistor 765 has a first terminal, a second terminal, and a control terminal. The first terminal of the transistor 765 is coupled to the supply terminal, which supplies the supply voltage. The second terminal of the transistor 765 is coupled to the transistors 770, 775, 780 and the third output of the control signal generation circuitry 700, which supplies the second control signal. The control terminal of the transistor 765 is coupled to the transistors 750, 770, the resistor 755, and the capacitor 760.

The transistor 770 has a first terminal, a second terminal, and a control terminal. The first terminal of the transistor 770 is coupled to the transistors 765, 775, 780 and the third output of the control signal generation circuitry 700, which supplies the second control signal. The second terminal of the transistor 770 is coupled to the common terminal, which supplies the common potential. The control terminal of the transistor 770 is coupled to the transistors 750, 765, the resistor 755, and the capacitor 760.

The transistor 775 has a first terminal, a second terminal, and a control terminal. The first terminal of the transistor 775 is coupled to the supply terminal, which supplies the supply voltage. The second terminal of the transistor 775 is coupled to the transistor 780 and the fourth output of the control signal generation circuitry 700, which supplies the second inverted control signal. The control terminal of the transistor 775 is coupled to the transistors 765, 770, 780 and the third output of the control signal generation circuitry 700, which supplies the second control signal.

The transistor 780 has a first terminal, a second terminal, and a control terminal. The first terminal of the transistor 780 is coupled to the transistor 775 and the fourth output of the control signal generation circuitry 700, which supplies the second inverted control signal. The second terminal of the transistor 780 is coupled to the common terminal, which supplies the common potential. The control terminal of the transistor 780 is coupled to the transistors 765, 770, 775 and the third output of the control signal generation circuitry 700, which supplies the second control signal.

In the example of FIG. 7A, the transistors 730, 740, 750, 770, 780 are n-channel MOSFETs. Alternatively, the transistors 730, 740, 750, 770, 780 may be n-channel FETs, n-channel IGBTs, n-channel JFETs, NPN BJTs or, with slight modifications, p-type equivalent devices. In the example of FIG. 7A, the transistors 725, 735, 745, 765, 775 are p-channel MOSFETs. Alternatively, the transistors 725, 735, 745, 765, 775 may be p-channel FETs, p-channel IGBTs, p-channel JFETs, PNP BJTs, or, with slight modifications, N-type equivalent devices. The transistors 725, 730, 735, 740, 745, 750, 765, 770, 775, 780 may be depletion mode devices, drain-extended devices, enhancement mode devices, natural transistors or other type of device structure transistors. Furthermore, the transistors 725, 730, 735, 740, 745, 750, 765, 770, 775, 780 may be implemented in/over a silicon substrate (Si), a silicon carbide substrate (SiC), a gallium nitride substrate (GaN) or a gallium arsenide substrate (GaAs).

FIG. 7B is a timing diagram 785 of example operations of the control signal generation circuitry 215, 700 of FIGS. 2 and 7A. In the example of FIG. 7B, the timing diagram 785 includes a first example control signal 790 (V_{OFF1}) and a second control signal 795 (V_{OFF2}). The first control signal 790 illustrates the state of the switch circuitry 260, 265 of FIG. 2 during an example transition from a power down state to normal operations. The second control signal 795 illustrates the state of the switch circuitry 240, 325, 410 of FIGS. 2, 3, 4, and 5 during the example transition from a power down state to normal operations.

In the example operations of the timing diagram 785, the transition from power down state to normal operation begins responsive to the falling edge of the first control signal 790. The resistor 755 and the capacitor 760 delay the falling edge of the first control signal 790 through the delay circuitry 715 to create a delay before generating a falling edge on the second control signal 795. The delay between falling edges of the control signals 790, 795 allows the amplifier circuitry 100, 200 time to settle before no longer driving the first input of the opposed-buffer stages 120, 205, 300, 400, 500, 610 of FIGS. 1, 2, 3, 4, 5, and 6 based on the second input of the opposed-buffer stages 120, 205, 300, 400, 500, 610. Advantageously, the timing constant of the resistor 755 and the capacitor 760 creates a delay between the control signals 790, 795. Advantageously, the delay between the control signals 790, 795 reduces transient voltages at the output of the amplifier circuitry 100, 200 when transitioning from the power down state to normal operations.

FIG. 8 is a flowchart representative of example machine-readable instructions or example operations 800 that may be at least one of executed, instantiated, or performed using an example implementation of the opposed-buffer stages 120, 205, 300, 400, 500, 610 of FIGS. 1, 2, 3, 4, 5, and 6 or more generally the amplifier circuitry 100, 200 of FIGS. 1 and 2. The example operations 800 of FIG. 8 begin at Block 805 at which, the control signal generation circuitry 215, 700 of FIGS. 2 and 7A determines if an amplifier is in a power down state. In some examples, the inverter circuitry 705 of FIG. 7A or more generally the control signal generation circuitry 215, 700 receives the reference control signal (V_{OFF0}). In such examples, the reference control signal controls the state of the amplifier circuitry 100, 200 responsive to inverter circuitry 705, 710, 720 of FIG. 7A and the delay circuitry 715 of FIG. 7A generating control signals (e.g., V_{OFF1}, ˜V_{OFF1}, V_{OFF2}, ˜V_{OFF2}) based on the reference control signal.

If the control signal generation circuitry 215, 700 determines that the amplifier is in a power down state (e.g., Block 805 returns a result of YES), the switch circuitry 260, 265 of FIG. 2 turns off output stage circuitry. (Block 810). In some examples, the inverter circuitry 705 generates the first inverted control signal (˜V_{OFF1}), which controls the switch circuitry 260 of FIG. 2, and the inverter circuitry 710 generates the first control signal (V_{OFF1}), which controls the switch circuitry 265 of FIG. 2. In example operations, the inverter circuitry 705 clears the first inverted control signal and the inverter circuitry 710 sets the first control signal responsive to the reference control signal being in a first state (e.g., logical one, logic high, etc.). In such example operations, the first control signal closes the switch circuitry 265 to disable the transistor 275 of FIG. 2 and the first inverted control signal closes switch circuitry 260 to disable the transistor 270 of FIG. 2.

The buffer circuitry 235, 320, 680 of FIGS. 2, 3, 4, 5, and 6 drive a first input of an opposed-buffer stage to a potential of a second input. (Block 815). In some examples, the delay circuitry 715 generates the second control signal (V_{OFF2}), which controls the switch circuitry 240, 325, 410, and the inverter circuitry 720 generates the second inverted control signal (˜V_{OFF2}), which may also control the switch circuitry 240, 325, 410. In example operations, the delay circuitry 715 sets the second control signal and the inverter circuitry 720 clears the second inverted control signal responsive to the first control signal being in a first state (e.g., logical one, logic high, etc.). In such example operations, the second control signal closes the switch circuitry 240 or enables the transistors 380, 430 of FIGS. 3, 4, 5, and 6 and the second inverted control signal enables the transistors 385, 420 of FIGS. 3, 4, 5, and 6. Advantageously, the switch circuitry 240, 325, 410 structures the buffer circuitry 235, 320, 680 to drive the first input of the opposed-buffer stage circuitry 120, 205, 300, 400, 500, 610 based on the second input of the opposed-buffer stage circuitry 120, 205, 300, 400, 500, 610 during the power down state.

In some examples, such as FIG. 4, structuring the switch circuitry 410 to control the supply of current to the transistors 370, 375 of FIGS. 3, 4, and 5 or more generally the buffer circuitry 320, decreases the impedance between the buffer circuitry 305, 320. Advantageously, such a positioning of the switch circuitry 410 reduces an impedance between the buffer circuitry 305, 320 when the switch circuitry 410 is closed. Advantageously, reducing the impedance between the buffer circuitry 305, 320 increases a drive strength of the output of the buffer circuitry 320 at the input of the buffer circuitry 305. Advantageously, the switch circuitry 410 reduces the power consumption of the buffer circuitry 320 during normal operation of the amplifier circuitry 100 responsive to preventing a supply of power to the transistors 370, 375.

In other examples, such as FIG. 5, structuring the current mirror circuitry 510, 520 to supply additional currents at the inverting input of the opposed-buffer stage 500 decreases the size of the transistors 370, 375. In such examples, the sizing of the transistors 530, 540, 550, 560 may be ratioed to supply a current multiple times the size of the current from the transistors 370, 375. For example, the transistors 370, 375 may be decreased by a factor of a ratio coefficient (n) plus one responsive to the transistors 540, 560 having a size of one to the ratio coefficient of the transistors 370, 375, 530, 550. Advantageously, using the current mirror circuitry 510, 520 to supply a portion of the current needed to set the inverting input of the opposed-buffer stage 500 decreases the size of the transistors 370, 375. Advantageously, decreasing the size of the transistors 370, 375 increases the linearity of the opposed-buffer stage 500 responsive to reducing the parasitic capacitance of relatively large transistors between the buffer circuitry 305, 320.

In yet another example, such as FIG. 6, structuring the input stage 605 to combine the currents from the current mirror circuitry 510, 520 using the transistors 635, 660 of FIG. 6 further improves linearity of the amplifier circuitry 100, 200. In some examples, a differential voltage (V_{IN_STAGE_DIFF}) between the inverting and non-inverting input voltages produces a gate-to-source voltage across the transistors 690, 692 of FIG. 6, which causes the buffer circuitry 680 to conduct current. In example operation, the current mirror circuitry 510, 520 supplies current to the transistors 635, 660 responsive to the transistors 690, 692 conducting current. In such example operations, the transistors 635, 660 drive the inverting input voltage at the input of the buffer circuitry 668, which reduces the differential voltage at the inputs of the opposed-buffer stage 610. Advantageously, using the transistors 635, 660 to drive the opposed-buffer stage 610 does not add additional parasitic capacitances at the inverting input of the opposed-buffer stage 610. In some examples, the operations of the transistors 635, 660 may be referred to as an injection cascode.

If the control signal generation circuitry 215, 700 determines that the amplifier is not in a power down state (e.g., Block 805 returns a result of NO) or control proceeds from Block 815, the control signal generation circuitry 215, 700 determines if the amplifier is leaving the power down state. (Block 820). In some examples, the inverter circuitry 705, 710, 720 and the delay circuitry 715 update the control signals responsive to changes in the reference control signal at the input of the control signal generation circuitry 215, 700. For example, the control signal generation circuitry 215, 700 may determine the amplifier circuitry 100, 200 is leaving the power down state responsive to a falling edge of the reference control signal.

If the control signal generation circuitry 215, 700 determines that the amplifier is leaving the power down state (e.g., Block 820 returns a result of YES), the switch circuitry 260, 265 turns on the output stage circuitry. (Block 825). In some examples, the inverter circuitry 705 generates the first inverted control signal (˜V_{OFF1}), which controls the switch circuitry 260, and the inverter circuitry 710 generates the first control signal (V_{OFF1}), which controls the switch circuitry 265. In example operations, the inverter circuitry 705 sets the first inverted control signal and the inverter circuitry 710 clears the first control signal responsive to the reference control signal being in a second state (e.g., logical zero, logic low, etc.). In such example operations, the first control signal opens the switch circuitry 265 to enable the transistor 275 and the first inverted control signal opens switch circuitry 260 to enable the transistor 270.

The control signal generation circuitry 215, 700 allows the amplifier to settle. (Block 830). In some examples, the resistor 755 of FIG. 7A and the capacitor 760 of FIG. 7A form a resistor-capacitor (RC) circuit having a resistor-capacitor time constant (also referred to as tau), which delays the falling edges. For example, the RC circuit of the resistor 755 and the capacitor 760 begins charging responsive to the falling edge of the first control signal enabling the transistor 745 of FIG. 7A and disabling the transistor 750 of FIG. 7A. In such examples, the capacitor 760 turns on the transistor 770 and turns off the transistor 765 after a delay that is proportional to the time the capacitor 760 charges. Such a delay between turning on the transistors 745, 770 provides time for the amplifier circuitry 100, 200 to settle after the inverter circuitry 705, 710 turns on the output stage 130, 210 of FIGS. 1 and 2.

The buffer circuitry 235, 320, 680 stops driving the first input of the opposed-buffer stage. (Block 835). In some examples, the delay circuitry 715 generates the second control signal (V_{OFF2}), which controls the switch circuitry 240, 325, 410, and the inverter circuitry 720 generates the second inverted control signal (˜V_{OFF2}), which may also control the switch circuitry 240, 325, 410. In example operations, the delay circuitry 715 clears the second control signal and the inverter circuitry 720 sets the second inverted control signal responsive to the first control signal being in a second state (e.g., logical zero, logic low, etc.). In such example operations, the second control signal opens the switch circuitry 240 or disables the transistors 380, 430 and the second inverted control signal opens the switch circuitry 240 or disables the transistors 385, 420. Advantageously, the switch circuitry 240, 325, 410 prevents the buffer circuitry 235, 320, 680 from driving the first input of the opposed-buffer stage circuitry 120, 205, 300, 400, 500, 610 after a delay that allows the amplifier circuitry 100, 200 time to settle. Advantageously, opening the switch circuitry 240, 325, 410 after allowing the amplifier circuitry 100, 200 time to settle reduces voltage transients at the output of the amplifier circuitry 100, 200.

If the control signal generation circuitry 215, 700 determines that the amplifier is not leaving the power down state (e.g., Block 820 returns a result of NO) of control proceeds from Block 835, the transconductance circuitry 615 of FIG. 6 receives an input voltage at inputs of an input stage circuitry. (Block 840). In example operations, the transconductance circuitry 615 produces currents responsive to a voltage difference between inverting and non-inverting inputs of the amplifier circuitry 100. In such example operations, the transistors 625, 650 of FIG. 6 supply the difference between the currents of the transconductance circuitry 615 and currents of the current source circuitry 620, 645 of FIG. 6 to inputs of the opposed-buffer stage 120, 205, 300, 400, 500, 610.

The input stage 110, 605 of FIGS. 1 and 6 generates a differential voltage based on the input voltage. (Block 845). In some examples, the currents through and the transconductances of the transistors 625, 635, 650, 660 set the input of the opposed-buffer stage 120, 205, 300, 400, 500, 610 proportional to the voltage difference between the inverting and non-inverting inputs of the amplifier circuitry 100, 200, 600. In other examples, such as FIG. 6, one input of the opposed-buffer stage 120, 205, 300, 400, 500, 610 may be fixed and the input stage 110, 605 generates the differential voltage responsive to setting the voltage at the second input of the opposed-buffer stage 120, 205, 300, 400, 500, 610.

The buffer circuitry 220, 230, 305, 315, 668 of FIGS. 2, 3, 4, 5, and 6 generates currents proportional to the voltages of the inputs of the opposed-buffer stage circuitry. (Block 850). In some examples, the buffer circuitry 220, 230, 305, 315, 668 generate the inverting sink current (I_{SNK-}), the non-inverting source current (I_{SRC+}), the non-inverting sink current (I_{SNK+}), and the inverting source current (I_{SRC-}) responsive to the differential voltage at the inputs of the opposed-buffer stages 205, 300, 400, 500, 610.

The output stage 130, 210 of FIGS. 1 and 2 drives an output voltage responsive to the currents of the opposed-buffer stage circuitry. (Block 855). In example operations, the buffer circuitry 220, 230, 305, 315, 668 sink the inverting and non-inverting sink currents from the current mirror circuitry 245 of FIG. 2 and supplies the inverting and non-inverting source currents to the current mirror circuitry 250 of FIG. 2. In such example operations, the class AB control circuitry 255 of FIG. 2 and the transistors 270, 275 of FIG. 2 generate the output voltage responsive to the difference between the inverting and non-inverting sink currents and the difference between the inverting and non-inverting source currents. Advantageously, the class AB control circuitry 255 linearly controls the transistors 270, 275 to generate an analog output.

Example methods are described with reference to the flowchart illustrated in FIG. 8. However, many other methods of implementing the opposed-buffer stages 120, 205, 300, 400, 500, 610 of FIGS. 1, 2, 3, 4, 5, and 6 or more generally the amplifier circuitry 100, 200 of FIGS. 1 and 2 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

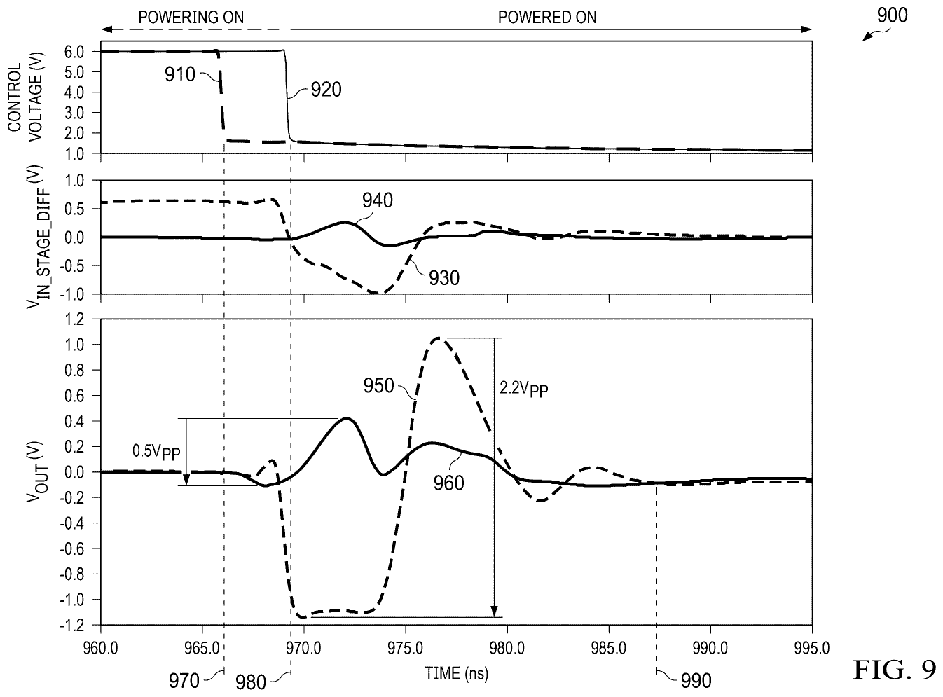

FIG. 9 is a timing diagram 900 of example operations of the opposed-buffer stages 120, 205, 300, 400, 500, 610 of FIGS. 1, 2, 3, 4, 5, and 6 or more generally the amplifier circuitry 100, 200 of FIGS. 1 and 2. In the example of FIG. 9, the timing diagram 900 includes a first example control signal 910, a second example control signal 920, an example uncompensated differential input voltage 930, an example compensated differential input voltage 940, an example uncompensated output voltage 950, and an example compensated output voltage 960.

The first control signal 910 illustrates the state of the switch circuitry 260, 265 of FIG. 2 during an example transition from a power down state to normal operations. The second control signal 920 illustrates the state of the switch circuitry 240, 325, 410 of FIGS. 2, 3, 4, 5, and 6 during the example transition from a power down state to normal operations. The uncompensated differential input voltage 930 illustrates the voltage difference between the inverting and non-inverting voltages at the input of the opposed-buffer stages 120, 205, 300, 400, 500, 610 without driving the first input based on the second input (e.g., not performing Block 815 of FIG. 8). The compensated differential input voltage 940 illustrates the voltage difference between the inverting and non-inverting voltages at the input of the opposed-buffer stages 120, 205, 300, 400, 500, 610 when driving the first input based on the second input (e.g., performing Block 815 of FIG. 8). The uncompensated output voltage 950 illustrates the output voltage of the amplifier circuitry 100, 200 responsive to the uncompensated differential input voltage 930. The compensated output voltage 960 illustrates the output voltage of the amplifier circuitry 100, 200 responsive to the compensated differential input voltage 940.

At a first time 970, the transition from power down state to normal operation begins responsive to the falling edge of the first control signal 910. At the first time 970, the compensated differential input voltage 940 remains approximately at zero volts responsive to the second control signal 920 remaining set. At a second time 980, the second control signal 920 has a falling edge, which prevents the buffer circuitry 235, 320, 680 from driving the first input of the opposed-buffer stages 120, 205, 300, 400, 500, 610. At approximately the second time 980, the uncompensated differential input voltage 930 is experiencing a transient spike. Such a transient of the uncompensated differential input voltage 930 produces a transient voltage on the uncompensated output voltage 950. However, between the second time 980 and a third time 990, the compensated differential input voltage 940 has a relatively smaller transient voltage. The relatively small transient voltage of the compensated differential input voltage 940 produces a relatively smaller voltage transient on the compensated output voltage 960. Advantageously, reducing the differential voltage at the inputs of the opposed-buffer stages 120, 205, 300, 400, 500, 610 reduces voltage transients during transitions from a power down state to normal operations.

FIG. 10 is a schematic diagram of example amplifier circuitry 1000 including an example opposed-buffer stage 1003, which is another example of the opposed-buffer stages 120, 205, 300, 400, 500, 610 of FIGS. 1, 2, 3, 4, 5, and 6, and an example output stage 1006, which is another example of the output stages 130, 210 of FIGS. 1 and 2. The example opposed-buffer stage 1003 of FIG. 10 includes first example buffer circuitry 1008, first example current source circuitry 1009, second example current source circuitry 1012, an example resistor 1015, and second example buffer circuitry 1018. The example buffer circuitry 1008 of FIG. 10 includes a first example transistor 1021, a second example transistor 1024, a third example transistor 1027, and a fourth example transistor 1030.

The example output stage 1006 of FIG. 10 includes first example current mirror circuitry 1033, second example current mirror circuitry 1036, first example current source circuitry 1039, second example current source circuitry 1042, first example gate biasing circuitry 1045, second example gate biasing circuitry 1048, example class AB control circuitry 1051, and example output driver circuitry 1054. The example current mirror circuitry 1033 of FIG. 10 includes a first example transistor 1057 and a second example transistor 1060. The example current mirror circuitry 1036 of FIG. 10 includes a first example transistor 1063 and a second example transistor 1066. The example gate biasing circuitry 1045 of FIG. 10 includes a first example transistor 1069 and a second example transistor 1072. The example gate biasing circuitry 1048 of FIG. 10 includes a first example transistor 1075 and a second example transistor 1078. The example class AB control circuitry 1051 of FIG. 10 includes a first example transistor 1081 and a second example transistor 1084. The example output driver circuitry 1054 of FIG. 10 includes a first example transistor 1087 and a second example transistor 1090.

The amplifier circuitry 1000 has a first input, a second input, and an output. The first input of the amplifier circuitry 1000 is structured to be coupled to the input stages 110, 605 of FIGS. 1 and 6, which supply an input voltage (V_{IN_STAGE}). The second input of the amplifier circuitry 1000 is structured to be coupled to a reference input, which supplies a reference voltage (V_{REF}). In some examples, the second input of the amplifier circuitry 1000 may be structured to receive a non-inverting input voltage, such as in the examples of FIGS. 2, 3, 4, and 5. The output of the amplifier circuitry 1000 is structured to be coupled to downstream circuitry, which receives an output voltage (V_{OUT}). In the example of FIG. 10, the amplifier circuitry 1000 includes the opposed-buffer stage 1003 and the output stage 1006. However, in some examples the amplifier circuitry 1000 includes an additional stage, such as the input stages 110, 605 of FIGS. 1 and 6.

The opposed-buffer stage 1003 has a first terminal, a second terminal, a third terminal, a fourth terminal, a fifth terminal, a sixth terminal, a seventh terminal, and an eighth terminal. The first terminal of the opposed-buffer stage 1003 is coupled to the first input of the amplifier circuitry 1000, which supplies the input voltage. The second terminal of the opposed-buffer stage 1003 is coupled to the second input of the amplifier circuitry 1000, which supplies the reference voltage. The third terminal of the opposed-buffer stage 1003 is coupled to the supply terminal, which supplies the supply voltage. The fourth, fifth, sixth, and seventh terminals of the opposed-buffer stage 1003 are coupled to the output stage 1006. The eighth terminal of the opposed-buffer stage 1003 is coupled to the common terminal, which supplies the common potential.

The output stage 1006 has a first terminal, a second terminal, a third terminal, a fourth terminal, a fifth terminal, a sixth terminal, and a seventh terminal. The first, second, third, and fourth terminals of the output stage 1006 are coupled to the opposed-buffer stage 1003. The fifth terminal of the output stage 1006 is coupled to the supply terminal, which supplies the supply voltage. The sixth terminal of the output stage 1006 is coupled to the common terminal, which supplies the common potential. The seventh terminal of the output stage 1006 is coupled to the output of the amplifier circuitry 1000, which supplies the output voltage to downstream circuitry.

The buffer circuitry 1008 has a first terminal, a second terminal, a third terminal, a fourth terminal, a fifth terminal, a sixth terminal, a seventh terminal, and an eighth terminal. The first terminal of the buffer circuitry 1008 is coupled to the first input of the amplifier circuitry 1000, which supplies the input voltage. The second terminal of the buffer circuitry 1008 is coupled to the current source circuitry 1009. The third terminal of the buffer circuitry 1008 is coupled to the current mirror circuitry 1033. The fourth terminal of the buffer circuitry 1008 is coupled to the gate biasing circuitry 1045. The fifth terminal of the buffer circuitry 1008 is coupled to the resistor 1015. The sixth terminal of the buffer circuitry 1008 is coupled to the gate biasing circuitry 1048. The seventh terminal of the buffer circuitry 1008 is coupled to the current mirror circuitry 1036. The eighth terminal of the buffer circuitry 1008 is coupled to the current source circuitry 1012.

The current source circuitry 1009 has a first terminal and a second terminal. The first terminal of the current source circuitry 1009 is coupled to the supply terminal, which supplies the supply voltage. The second terminal of the current source circuitry 1009 is coupled to the transistors 1021, 1027.

The current source circuitry 1012 has a first terminal and a second terminal. The first terminal of the current source circuitry 1012 is coupled to the transistors 1024, 1030. The second terminal of the current source circuitry 1012 is coupled to the common terminal, which supplies the common potential.

The resistor 1015 has a first terminal and a second terminal. The first terminal of the resistor 1015 is coupled to the transistors 1027, 1030. The second terminal of the resistor 1015 is coupled to the buffer circuitry 1018.

The buffer circuitry 1018 has a first terminal, a second terminal, a third terminal, and a fourth terminal. The first terminal of the buffer circuitry 1018 is coupled to the second input of the amplifier circuitry 1000, which supplies the reference voltage. The second terminal of the buffer circuitry 1018 is coupled to the resistor 1015. The third terminal of the buffer circuitry 1018 is coupled to the current mirror circuitry 1033, the current source circuitry 1039, the class AB control circuitry 1051, and the output driver circuitry 1054. The fourth terminal of the buffer circuitry 1018 is coupled to the current mirror circuitry 1036, the current source circuitry 1042, the class AB control circuitry 1051, and the output driver circuitry 1054.

The transistor 1021 has a first terminal, a second terminal, and a control terminal. The first terminal of the transistor 1021 is coupled to the current source circuitry 1009 and the transistor 1027. The second terminal of the transistor 1021 is coupled to the gate biasing circuitry 1048 and the class AB control circuitry 1051. The control terminal of the transistor 1021 is coupled to the transistor 1024 and the first input of the amplifier circuitry 1000, which supplies the input voltage.

The transistor 1024 has a first terminal, a second terminal, and a control terminal. The first terminal of the transistor 1024 is coupled to the gate biasing circuitry 1045 and the class AB control circuitry 1051. The second terminal of the transistor 1024 is coupled to the current source circuitry 1012 and the transistor 1030. The control terminal of the transistor 1024 is coupled to the transistor 1021 and the first input of the amplifier circuitry 1000, which supplies the input voltage.

The transistor 1027 has a first terminal, a second terminal, and a control terminal. The first terminal of the transistor 1027 is coupled to the current mirror circuitry 1033. The second terminal of the transistor 1027 is coupled to the resistor 1015 and the transistor 1030. The control terminal of the transistor 1027 is coupled to the current source circuitry 1009 and the transistor 1021.

The transistor 1030 has a first terminal, a second terminal, and a control terminal. The first terminal of the transistor 1030 is coupled to the resistor 1015 and the transistor 1027. The second terminal of the transistor 1030 is coupled to the current mirror circuitry 1036. The control terminal of the transistor 1030 is coupled to the current source circuitry 1012 and the transistor 1024.

The current mirror circuitry 1033 has a first terminal, a second terminal, and a third terminal. The first terminal of the current mirror circuitry 1033 is coupled to the buffer circuitry 1008. The second terminal of the current mirror circuitry 1033 is coupled to the buffer circuitry 1018, the current source circuitry 1039, the class AB control circuitry 1051, and the output driver circuitry 1054. The third terminal of the current mirror circuitry 1033 is coupled to the supply terminal, which supplies the supply voltage.

The current mirror circuitry 1036 has a first terminal, a second terminal, and a third terminal. The first terminal of the current mirror circuitry 1036 is coupled to the buffer circuitry 1008. The second terminal of the current mirror circuitry 1036 is coupled to the buffer circuitry 1018, the current source circuitry 1042, the class AB control circuitry 1051, and the output driver circuitry 1054. The third terminal of the current mirror circuitry 1036 is coupled to the common terminal, which supplies the common potential.

The current source circuitry 1039 has a first terminal and a second terminal. The first terminal of the current source circuitry 1039 is coupled to the supply terminal, which supplies the supply voltage. The second terminal of the current source circuitry 1039 is coupled to the buffer circuitry 1018, the current mirror circuitry 1033, the class AB control circuitry 1051, and the output driver circuitry 1054.

The current source circuitry 1042 has a first terminal and a second terminal. The first terminal of the current source circuitry 1042 is coupled to the buffer circuitry 1018, the current mirror circuitry 1036, the class AB control circuitry 1051, and the output driver circuitry 1054. The second terminal of the current source circuitry 1042 is coupled to the common terminal, which supplies the common potential.

The gate biasing circuitry 1045 has a first terminal and a second terminal. The first terminal of the gate biasing circuitry 1045 is coupled to the supply terminal, which supplies the supply voltage. The second terminal of the gate biasing circuitry 1045 is coupled to the buffer circuitry 1008 and the class AB control circuitry 1051.

The gate biasing circuitry 1048 has a first terminal and a second terminal. The first terminal of the gate biasing circuitry 1048 is coupled to the buffer circuitry 1008 and the class AB control circuitry 1051. The second terminal of the gate biasing circuitry 1048 is coupled to the common terminal, which supplies the common potential.

The class AB control circuitry 1051 has a first terminal, a second terminal, a third terminal, and a fourth terminal. The first terminal of the class AB control circuitry 1051 is coupled to the buffer circuitry 1018, the current mirror circuitry 1033, the current source circuitry 1039, and the output driver circuitry 1054. The second terminal of the class AB control circuitry 1051 is coupled to the buffer circuitry 1008 and the gate biasing circuitry 1045. The third terminal of the class AB control circuitry 1051 is coupled to the buffer circuitry 1008 and the gate biasing circuitry 1048. The fourth terminal of the class AB control circuitry 1051 is coupled to the buffer circuitry 1018, the current mirror circuitry 1036, the current source circuitry 1042, and the output driver circuitry 1054.

The output driver circuitry 1054 has a first terminal, a second terminal, a third terminal, a fourth terminal, and a fifth terminal. The first terminal of the output driver circuitry 1054 is coupled to the supply terminal, which supplies the supply voltage. The second terminal of the output driver circuitry 1054 is coupled to the buffer circuitry 1018, the current mirror circuitry 1033, the current source circuitry 1039, and the class AB control circuitry 1051. The third terminal of the output driver circuitry 1054 is coupled to the output of the amplifier circuitry 1000. The fourth terminal of the output driver circuitry 1054 is coupled to the buffer circuitry 1018, the current mirror circuitry 1036, the current source circuitry 1042, and the class AB control circuitry 1051. The fifth terminal of the output driver circuitry 1054 is coupled to the common terminal, which supplies the common potential.

The transistor 1057 has a first terminal, a second terminal, and a control terminal. The first terminal of the transistor 1057 is coupled to the supply terminal, which supplies the supply voltage. The second and control terminals of the transistor 1057 are coupled to the transistors 1027, 1060.

The transistor 1060 has a first terminal, a second terminal, and a control terminal. The first terminal of the transistor 1060 is coupled to the supply terminal, which supplies the supply voltage. The second terminal of the transistor 1060 is coupled to the buffer circuitry 1018, the current source circuitry 1039, and the transistors 1081, 1084, 1087. The control terminal of the transistor 1060 is coupled to the transistors 1027, 1057.

The transistor 1063 has a first terminal, a second terminal, and a control terminal. The first and control terminals of the transistor 1063 are coupled to the transistors 1030, 1066. The second terminal of the transistor 1063 is coupled to the common terminal, which supplies the common potential.

The transistor 1066 has a first terminal, a second terminal, and a control terminal. The first terminal of the transistor 1066 is coupled to the buffer circuitry 1018, the current source circuitry 1042, and the transistors 1081, 1084, 1090. The second terminal of the transistor 1066 is coupled to the common terminal, which supplies the common potential. The control terminal of the transistor 1066 is coupled to the transistors 1030, 1063.

The transistor 1069 has a first terminal, a second terminal, and a control terminal. The first terminal of the transistor 1069 is coupled to the supply terminal, which supplies the supply voltage. The second and control terminals of the transistor 1069 are coupled to the transistor 1072.

The transistor 1072 has a first terminal, a second terminal, and a control terminal. The first terminal of the transistor 1072 is coupled to the transistor 1069. The second and control terminals of the transistor 1072 are coupled to the transistors 1024, 1084.

The transistor 1075 has a first terminal, a second terminal, and a control terminal. The first and control terminals of the transistor 1075 are coupled to the transistors 1021, 1081. The second terminal of the transistor 1075 is coupled to the transistor 1078.

The transistor 1078 has a first terminal, a second terminal, and a control terminal. The first and control terminals of the transistor 1078 are coupled to the transistor 1075. The second terminal of the transistor 1078 is coupled to the common terminal, which supplies the common potential.

The transistor 1081 has a first terminal, a second terminal, and a control terminal. The first terminal of the transistor 1081 is coupled to the buffer circuitry 1018, the current source circuitry 1039, and the transistors 1060, 1084, 1087. The second terminal of the transistor 1081 is coupled to the buffer circuitry 1018, the current source circuitry 1042, and the transistors 1066, 1084, 1090. The control terminal of the transistor 1081 is coupled to the transistors 1021, 1075.

The transistor 1084 has a first terminal, a second terminal, and a control terminal. The first terminal of the transistor 1084 is coupled to the buffer circuitry 1018, the current source circuitry 1039, and the transistors 1060, 1081, 1087. The second terminal of the transistor 1084 is coupled to the buffer circuitry 1018, the current source circuitry 1042, and the transistors 1066, 1081, 1090. The control terminal of the transistor 1084 is coupled to the transistors 1024, 1072.

The transistor 1087 has a first terminal, a second terminal, and a control terminal. The first terminal of the transistor 1087 is coupled to the supply terminal, which supplies the supply voltage. The second terminal of the transistor 1087 is coupled to the transistor 1090 and the output of the amplifier circuitry 1000. The control terminal of the transistor 1087 is coupled to the buffer circuitry 1018, the current source circuitry 1039, and the transistors 1060, 1081, 1084.

The transistor 1090 has a first terminal, a second terminal, and a control terminal. The first terminal of the transistor 1090 is coupled to the transistor 1087 and the output of the amplifier circuitry 1000. The second terminal of the transistor 1090 is coupled to the common terminal, which supplies the common potential. The control terminal of the transistor 1090 is coupled to the buffer circuitry 1018, the current source circuitry 1042, and the transistors 1066, 1081, 1084.

In the example of FIG. 10, the transistors 1024, 1027, 1063, 1066, 1075, 1078, 1081, 1090 are n-channel MOSFETs. Alternatively, the transistors 1024, 1027, 1063, 1066, 1075, 1078, 1081, 1090 may be n-channel FETs, n-channel IGBTs, n-channel JFETs, NPN BJTs or, with slight modifications, p-type equivalent devices. In the example of FIG. 10, the transistors 1021, 1030, 1057, 1060, 1069, 1072, 1084, 1087 are p-channel MOSFETs. Alternatively, the transistors 1021, 1030, 1057, 1060, 1069, 1072, 1084, 1087 may be p-channel FETs, p-channel IGBTs, p-channel JFETs, PNP BJTs, or, with slight modifications, N-type equivalent devices. The transistors 1021, 1024, 1027, 1030, 1057, 1060, 1063, 1066, 1069, 1072, 1075, 1078, 1081, 1084, 1087, 1090 may be depletion mode devices, drain-extended devices, enhancement mode devices, natural transistors or other type of device structure transistors. Furthermore, the transistors 1021, 1024, 1027, 1030, 1057, 1060, 1063, 1066, 1069, 1072, 1075, 1078, 1081, 1084, 1087, 1090 may be implemented in/over a silicon substrate (Si), a silicon carbide substrate (SiC), a gallium nitride substrate (GaN) or a gallium arsenide substrate (GaAs).

Advantageously, the transistor 1021 supplies current from the current source circuitry 1009 to the gate biasing circuitry 1048. Advantageously, the transistor 1021 replaces an additional current source to bias the gate biasing circuitry 1048. Advantageously, the transistor 1024 supplies current from the gate biasing circuitry 1045 to the current source circuitry 1012. Advantageously, the transistor 1024 replaces an additional current source to bias the gate biasing circuitry 1045.

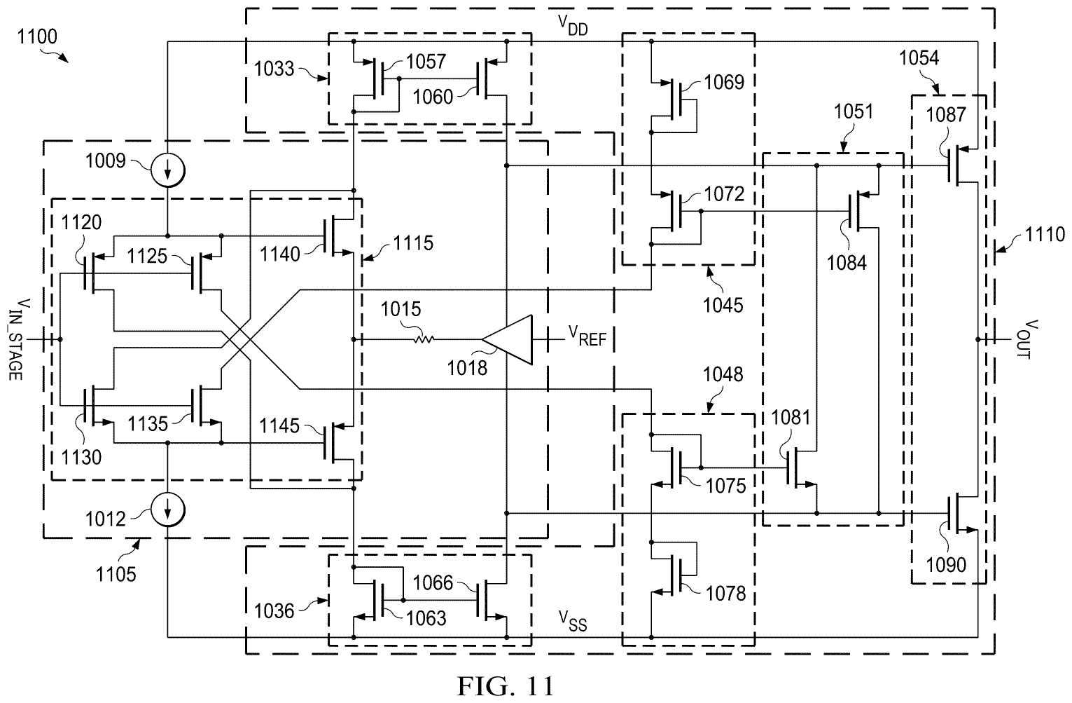

FIG. 11 is a schematic diagram of example amplifier circuitry 1100 including an example opposed-buffer stage 1105, which is another example of the opposed-buffer stages 120, 205, 300, 400, 500, 610, 1003 of FIGS. 1, 2, 3, 4, 5, 6, and 10, and an example output stage 1110, which is another example of the output stage 130, 210, 1006 of FIGS. 1, 2, and 10. The example opposed-buffer stage 1105 of FIG. 11 includes the current source circuitry 1009, 1012 of FIG. 10, the resistor 1015 of FIG. 10, the buffer circuitry 1018 of FIG. 10, and example buffer circuitry 1115. The example buffer circuitry 1115 of FIG. 11 includes a first example transistor 1120, a second example transistor 1125, a third example transistor 1130, a fourth example transistor 1135, a fifth example transistor 1140, and a sixth example transistor 1145.

The example output stage 1110 of FIG. 11 includes the current mirror circuitry 1033, 1036 of FIG. 10, the gate biasing circuitry 1045, 1048 of FIG. 10, the class AB control circuitry 1051 of FIG. 10, and the output driver circuitry 1054 of FIG. 10. The example current mirror circuitry 1033 of FIG. 11 includes the transistors 1057, 1060 of FIG. 10. The example current mirror circuitry 1036 of FIG. 11 includes the transistor 1063, 1066 of FIG. 10. The example gate biasing circuitry 1045 of FIG. 11 includes the transistors 1069, 1072 of FIG. 10. The example gate biasing circuitry 1048 of FIG. 11 includes the transistors 1075, 1078 of FIG. 10. The example class AB control circuitry 1051 of FIG. 11 includes the transistors 1081, 1084 of FIG. 10. The example output driver circuitry 1054 of FIG. 11 includes the transistors 1087, 1090 of FIG. 10.

The amplifier circuitry 1100 has a first input, a second input, and an output. The first input of the amplifier circuitry 1100 is structured to be coupled to the input stages 110, 605 of FIGS. 1 and 6, which supply an input voltage (V_{IN_STAGE}). The second input of the amplifier circuitry 1100 is structured to be coupled to a reference input, which supplies a reference voltage (V_{REF}). The output of the amplifier circuitry 1100 is structured to be coupled to downstream circuitry, which receives an output voltage (V_{OUT}). In the example of FIG. 11, the amplifier circuitry 1100 includes the opposed-buffer stage 1105 and the output stage 1110. However, in some examples the amplifier circuitry 1100 includes an additional stage, such as the input stages 110, 605 of FIGS. 1 and 6.

The buffer circuitry 1115 has a first terminal, a second terminal, a third terminal, a fourth terminal, a fifth terminal, a sixth terminal, a seventh terminal, and an eighth terminal. The first terminal of the buffer circuitry 1115 is coupled to the first input of the amplifier circuitry 1100, which supplies the input voltage. The second terminal of the buffer circuitry 1115 is coupled to the current source circuitry 1009. The third terminal of the buffer circuitry 1115 is coupled to the current mirror circuitry 1033. The fourth terminal of the buffer circuitry 1115 is coupled to the gate biasing circuitry 1045. The fifth terminal of the buffer circuitry 1115 is coupled to the resistor 1015. The sixth terminal of the buffer circuitry 1115 is coupled to the gate biasing circuitry 1048. The seventh terminal of the buffer circuitry 1115 is coupled to the current mirror circuitry 1036. The eighth terminal of the buffer circuitry 1115 is coupled to the current source circuitry 1012. The buffer circuitry 1115 is another example of the buffer circuitry 1008 of FIG. 10.

The transistor 1120 has a first terminal, a second terminal, and a control terminal. The first terminal of the transistor 1120 is coupled to the current source circuitry 1009 and the transistors 1125, 1140. The second terminal of the transistor 1120 is coupled to the current mirror circuitry 1036 and the transistor 1145. The control terminal of the transistor 1120 is coupled to the transistors 1125, 1130, 1135 and the first input of the amplifier circuitry 1100, which supplies the input voltage.

The transistor 1125 has a first terminal, a second terminal, and a control terminal. The first terminal of the transistor 1125 is coupled to the current source circuitry 1009 and the transistors 1120, 1140. The second terminal of the transistor 1125 is coupled to the gate biasing circuitry 1048. The control terminal of the transistor 1125 is coupled to the transistors 1120, 1130, 1135 and the first input of the amplifier circuitry 1100, which supplies the input voltage.

The transistor 1130 has a first terminal, a second terminal, and a control terminal. The first terminal of the transistor 1130 is coupled to the current mirror circuitry 1033 and the transistor 1140. The second terminal of the transistor 1130 is coupled to the current source circuitry 1012 and the transistors 1135, 1145. The control terminal of the transistor 1130 is coupled to the transistors 1120, 1125, 1135 and the first input of the amplifier circuitry 1100, which supplies the input voltage.

The transistor 1135 has a first terminal, a second terminal, and a control terminal. The first terminal of the transistor 1135 is coupled to the gate biasing circuitry 1045. The second terminal of the transistor 1135 is coupled to the current source circuitry 1012 and the transistors 1130, 1145. The control terminal of the transistor 1135 is coupled to the transistors 1120, 1125, 1130 and the first input of the amplifier circuitry 1100, which supplies the input voltage.

The transistor 1140 has a first terminal, a second terminal, and a control terminal. The first terminal of the transistor 1140 is coupled to the current mirror circuitry 1033 and the transistor 1130. The second terminal of the transistor 1140 is coupled to the resistor 1015 and the transistor 1145. The control terminal of the transistor 1140 is coupled to the current source circuitry 1009 and the transistors 1120, 1125.

The transistor 1145 has a first terminal, a second terminal, and a control terminal. The first terminal of the transistor 1145 is coupled to the resistor 1015 and the transistor 1140. The second terminal of the transistor 1145 is coupled to the current mirror circuitry 1036 and the transistor 1120. The control terminal of the transistor 1145 is coupled to the current source circuitry 1012 and the transistors 1130, 1135.

In the example of FIG. 11, the transistors 1063, 1066, 1075, 1078, 1081, 1090, 1130, 1135, 1140 are n-channel MOSFETs. Alternatively, the transistors 1063, 1066, 1075, 1078, 1081, 1090, 1130, 1135, 1140 may be n-channel FETs, n-channel IGBTs, n-channel JFETs, NPN BJTs or, with slight modifications, p-type equivalent devices. In the example of FIG. 11, the transistors 1057, 1060, 1069, 1072, 1084, 1087, 1120, 1125, 1145 are p-channel MOSFETs. Alternatively, the transistors 1057, 1060, 1069, 1072, 1084, 1087, 1120, 1125, 1145 may be p-channel FETs, p-channel IGBTs, p-channel JFETs, PNP BJTs, or, with slight modifications, N-type equivalent devices. The transistors 1057, 1060, 1063, 1066, 1069, 1072, 1075, 1078, 1081, 1084, 1087, 1090, 1120, 1125, 1130, 1135, 1140, 1145 may be depletion mode devices, drain-extended devices, enhancement mode devices, natural transistors or other type of device structure transistors. Furthermore, the transistors 1057, 1060, 1063, 1066, 1069, 1072, 1075, 1078, 1081, 1084, 1087, 1090, 1120, 1125, 1130, 1135, 1140, 1145 may be implemented in/over a silicon substrate (Si), a silicon carbide substrate (SiC), a gallium nitride substrate (GaN) or a gallium arsenide substrate (GaAs).

Advantageously, the transistor 1120 supplies current from the current source circuitry 1009 to the current mirror circuitry 1036. Advantageously, the transistor 1120 replaces the current source circuitry 1042 of FIG. 10. Advantageously, the transistor 1125 supplies current from the current source circuitry 1009 to the gate biasing circuitry 1048. Advantageously, the transistor 1125 replaces an additional current source to bias the gate biasing circuitry 1048.

Advantageously, the transistor 1130 supplies current from the current mirror circuitry 1033 to the current source circuitry 1012. Advantageously, the transistor 1130 replaces the current source circuitry 1039 of FIG. 10. Advantageously, the transistor 1135 supplies current from the gate biasing circuitry 1045 to the current source circuitry 1012. Advantageously, the transistor 1135 replaces an additional current source to bias the gate biasing circuitry 1045.

In the example of FIG. 10, the transistors 1021, 1024 bias the gate biasing circuitry 1045, 1048 using the current source circuitry 1009, 1012. However, the input voltage modifies the conduction of current by the transistors 1021, 1024, which makes the bias current of gate biasing circuitry 1045, 1048 dependent on the input voltage. Advantageously, in the examples of FIG. 11 the current source circuitry 1009, 1012 are structured to bias both the gate biasing circuitry 1045, 1048 and the class AB control circuitry 1051. In such examples, the transistors 1120, 1125, 1130, 1135 are sized to proportionally distribute currents from the current source circuitry 1009, 1012 to one of the gate biasing circuitry 1045, 1048 or the current mirror circuitry 1033, 1036. Similarly to the bias currents of the transistors 1021, 1024, 1125, 1135, the bias currents of the transistors 1120, 1130 are also dependent on the input voltage.

Advantageously, the gate biasing circuitry 1045, 1048 set the voltage of the control terminals of the transistors 1081, 1084 and the bias currents mirrored by the current mirror circuitry 1033, 1036, 1315, 1325 bias the source terminals of the transistors 1081, 1084. In such examples, the ratio of the sizing of the transistors 1120, 1125 and the transistors 1130, 1135 can be set to cancel out the signal dependency of the bias currents. To cancel out biasing errors resulting from the signal dependency of the currents through the transistors 1120, 1125, 1130, 1135, a first voltage error (v_{err1A}) is approximately equal to a second voltage error (v_{err1B}). The first voltage error represents the signal dependent component of the voltage at the control terminal of transistor 1081 resulting from the signal dependent component of the bias current from the transistor 1125 through the transistors 1075, 1078. The second voltage error represents the signal dependent component of the voltage between the control terminal and the source terminal of transistor 1081 resulting from the signal dependent component of the bias current from the transistor 1120 though the current mirror circuitry 1036 and the transconductance of the transistor 1081.

The first voltage error corresponds to the change in voltage at the control terminal of the transistor 1081 responsive to the signal-dependent component (i_{err1A}) of the gate bias current from the transistor 1125 times one over the transconductance of the transistors 1075, 1078 (gₘ₁, gₘ₂). The transconductance of the transistors 1075, 1078 is proportional to the square root of a first total current through the transistors 1075, 1078 (I_{1A}) time the ratio of the width to length of the channel of the transistors 1075, 1078 ([W/L]₁, [W/L]₂). The first voltage error at the control terminal of the transistor 1081 is represented using Equation (1), below.

$${v}_{err 1 A} = {i}_{err 1 A} ( \frac{1}{{g}_{m 1}} + \frac{1}{{g}_{m 2}} ) ∝ {i}_{err 1 A} ( \frac{1}{\sqrt{{I}_{1 A} * {[ W / L ]}_{1}}} + \frac{1}{\sqrt{{I}_{1 A} * {[ W / L ]}_{2}}} ) = \frac{{i}_{err 1 A}}{\sqrt{{I}_{1 A}}} ( \frac{1}{\sqrt{{[ W / L ]}_{1}}} + \frac{1}{\sqrt{{[ W / L ]}_{2}}} ) ; \qquad Equation ( 1 )$$

The second voltage error corresponds to the change in voltage between the control and source terminals of the transistor 1081 responsive to the signal dependent component (i_{err1B}) of the source bias current from the transistor 1120, which the current mirror circuitry 1036 mirrors, times one over the transconductance of the transistor 1081 (gₘ₃). The signal dependent component of the source bias current corresponds to the portion of the total signal dependent bias current component through transistors 1120, 1125 in comparison to the ratio of the total currents through the transistors 1120, 1125. The ratio of the currents through the transistors 1120, 1125 is proportional to the width to length of the channel of the transistors 1120, 1125 ([W/L]_{1B}, [W/L]_{1A}). The transconductance of the transistor 1081 is proportional to the square root of the first total current (I_{1B}) through the transistor 1081 times the ratio of the width to length of the channel of the transistor 1081 ([W/L]₃). The first voltage error between the control and source terminals of the transistor 1081 is represented using Equation (2), below.

$${v}_{err 1 B} = {i}_{err 1 B} ( \frac{1}{{g}_{m 3}} ) = {i}_{err 1 A} ( \frac{{[ W / L ]}_{1 B}}{{[ W / L ]}_{1 A}} ) ( \frac{1}{{g}_{m 3}} ) ∝ {i}_{err 1 A} ( \frac{{[ W / L ]}_{1 B}}{{[ W / L ]}_{1 A}} ) ( \frac{1}{\sqrt{\frac{{I}_{1 B}}{2} * {[ W / L ]}_{3}}} ) = {i}_{err 1 A} ( \frac{{[ W / L ]}_{1 B}}{{[ W / L ]}_{1 A}} ) ( \frac{1}{\sqrt{\frac{{I}_{1 A}}{2} ( \frac{{[ W / L ]}_{1 B}}{{[ W / L ]}_{1 A}} ) * {[ W / L ]}_{3}}} ) = {i}_{err 1 A} ( \frac{\sqrt{\frac{{[ W / L ]}_{1 B}}{{[ W / L ]}_{1 A}}}}{\sqrt{\frac{{I}_{1 A}}{2} * {[ W / L ]}_{3}}} ) ; \qquad Equation ( 2 )$$

As mentioned above, in order to remove the signal dependent bias error on the source voltage of the transistor 1081, the first voltage error must be set equal to the second voltage error. In such examples, voltage error resulting from signal dependent bias current components cancel. Such a cancelation of the first and second voltage errors is achieved by satisfying Equation (3), below.

$$\frac{{i}_{err 1 A}}{\sqrt{{I}_{1 A}}} ( \frac{1}{\sqrt{{[ W / L ]}_{1}}} + \frac{1}{{[ W / L ]}_{2}} ) = ( \frac{\sqrt{\frac{{[ W / L ]}_{1 B}}{{[ W / L ]}_{1 A}}}}{\sqrt{\frac{{I}_{1 A}}{2} * {[ W / L ]}_{3}}} ) ; \qquad Equation ( 3 )$$

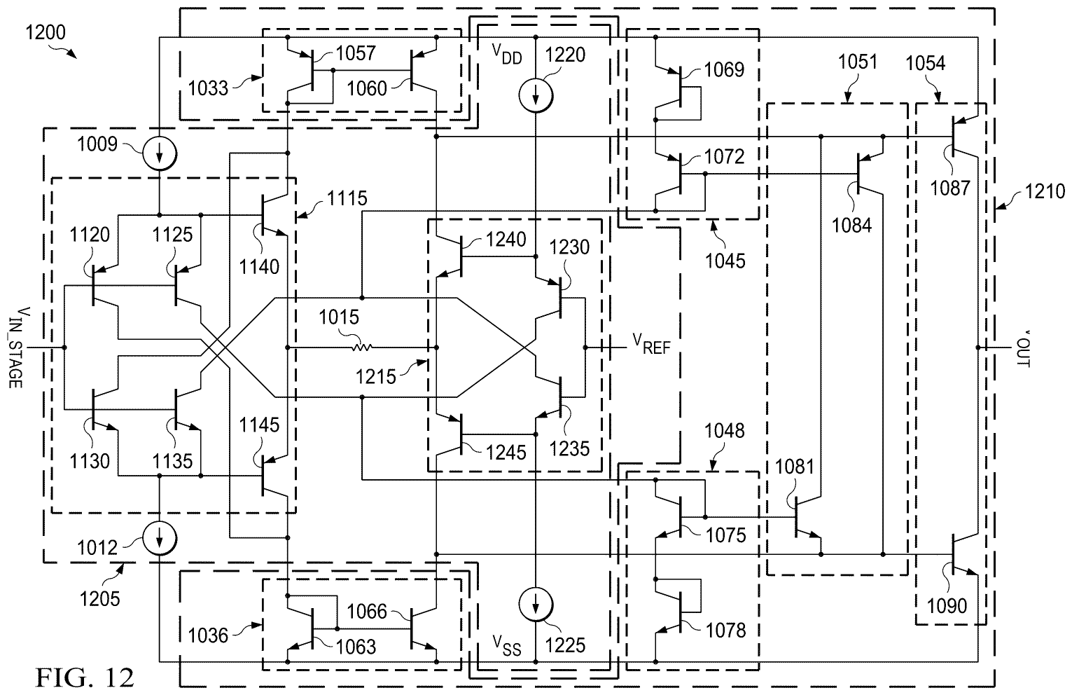

Equation (3), above, may be reduced to produce Equation (4), below. Advantageously, sizing the channels of the transistors 1075, 1078, 1081, 1120, 1125 to comply with Equation (4) reduces signal error resulting from bias dependency on the input voltage. Similarly, Equation (5), below, provides the corresponding requirement for the channels of the transistors 1069, 1072, 1084, 1130, 1135 ([W/L]₄, [W/L]₅, [W/L]₆, [W/L]_{2B}, [W/L]_{2A}). Alternatively, as illustrated in FIG. 12, in some examples, implementing the transistors of the amplifier circuitry 1100 using BJTs removes the ratio dependency of Equations (4) and (5).

$$\frac{1}{\sqrt{{[ W / L ]}_{1}}} + \frac{1}{\sqrt{{[ W / L ]}_{2}}} = \sqrt{\frac{2}{{[ W / L ]}_{3}} * \frac{{[ W / L ]}_{1 B}}{{[ W / L ]}_{1 A}}} ; \qquad Equation ( 4 )$$

$$\frac{1}{\sqrt{{[ W / L ]}_{4}}} + \frac{1}{\sqrt{{[ W / L ]}_{5}}} = \sqrt{\frac{2}{{[ W / L ]}_{6}} * \frac{{[ W / L ]}_{2 B}}{{[ W / L ]}_{2 A}}} ; \qquad Equation ( 5 )$$

FIG. 12 is a schematic diagram of example amplifier circuitry 1200 including an example opposed-buffer stage 1205, which is another example of the opposed-buffer stages 120, 205, 300, 400, 500, 610, 1003, 1105 of FIGS. 1, 2, 3, 4, 5, 6, 10, and 11, and an example output stage 1210, which is another example of the output stage 130, 210, 1006, 1110 of FIGS. 1, 2, 10, and 11. The example opposed-buffer stage 1205 of FIG. 12 includes the current source circuitry 1009, 1012 of FIG. 10, the resistor 1015 of FIG. 10, the buffer circuitry 1115 of FIG. 11, example buffer circuitry 1215, first example current source circuitry 1220, and second example current source circuitry 1225. The example buffer circuitry 1115 of FIG. 12 includes the transistors 1120, 1125, 1130, 1135, 1140, 1145 of FIG. 11. The example buffer circuitry 1215 of FIG. 12 includes a first example transistor 1230, a second example transistor 1235, a third example transistor 1240, and a fourth example transistor 1245.

The example output stage 1210 of FIG. 12 includes the current mirror circuitry 1033, 1036 of FIG. 10, the gate biasing circuitry 1045, 1048 of FIG. 10, the class AB control circuitry 1051 of FIG. 10, and the output driver circuitry 1054 of FIG. 10. The example current mirror circuitry 1033 of FIG. 12 includes the transistors 1057, 1060 of FIG. 10. The example current mirror circuitry 1036 of FIG. 12 includes the transistors 1063, 1066 of FIG. 10. The example gate biasing circuitry 1045 of FIG. 12 includes the transistors 1069, 1072 of FIG. 10. The example gate biasing circuitry 1048 of FIG. 12 includes the transistors 1075, 1078 of FIG. 10. The example class AB control circuitry 1051 of FIG. 12 includes the transistors 1081, 1084 of FIG. 10. The example output driver circuitry 1054 of FIG. 12 includes the transistors 1087, 1090 of FIG. 10.

The amplifier circuitry 1200 has a first input, a second input, and an output. The first input of the amplifier circuitry 1200 is structured to be coupled to the input stages 110, 605 of FIGS. 1 and 6, which supply an input voltage (V_{IN_STAGE}). The second input of the amplifier circuitry 1200 is structured to be coupled to a reference input, which supplies a reference voltage (V_{REF}). The output of the amplifier circuitry 1200 is structured to be coupled to downstream circuitry, which receives an output voltage (V_{OUT}). In the example of FIG. 12, the amplifier circuitry 1200 includes the opposed-buffer stage 1205 and the output stage 1210. However, in some examples the amplifier circuitry 1200 includes an additional stage, such as the input stages 110, 605 of FIGS. 1 and 6.

The buffer circuitry 1215 has a first terminal, a second terminal, a third terminal, a fourth terminal, a fifth terminal, a sixth terminal, a seventh terminal, and an eighth terminal. The first terminal of the buffer circuitry 1215 is coupled to the second input of the amplifier circuitry 1200, which supplies the reference voltage. The second terminal of the buffer circuitry 1215 is coupled to the current source circuitry 1220. The third terminal of the buffer circuitry 1215 is coupled to the current mirror circuitry 1033. The fourth terminal of the buffer circuitry 1215 is coupled to the gate biasing circuitry 1045 and the buffer circuitry 1115. The fifth terminal of the buffer circuitry 1215 is coupled to the resistor 1015. The sixth terminal of the buffer circuitry 1215 is coupled to the gate biasing circuitry 1048 and the class AB control circuitry 1051. The seventh terminal of the buffer circuitry 1215 is coupled to the current mirror circuitry 1036. The eighth terminal of the buffer circuitry 1215 is coupled to the current source circuitry 1225.

The current source circuitry 1220 has a first terminal and a second terminal. The first terminal of the current source circuitry 1220 is coupled to the supply terminal, which supplies the supply voltage. The second terminal of the current source circuitry 1220 is coupled to the buffer circuitry 1215.

The current source circuitry 1225 has a first terminal and a second terminal. The first terminal of the current source circuitry 1225 is coupled to the buffer circuitry 1215. The second terminal of the current source circuitry 1225 is coupled to the common terminal, which supplies the common potential.

The transistor 1230 has a first terminal, a second terminal, and a control terminal. The first terminal of the transistor 1230 is coupled to the current source circuitry 1220 and the transistor 1240. The second terminal of the transistor 1230 is coupled to the gate biasing circuitry 1048, the class AB control circuitry 1051, and the buffer circuitry 1115. The control terminal of the transistor 1230 is coupled to the transistor 1235 and the second input of the amplifier circuitry 1200, which supplies the reference voltage.

The transistor 1235 has a first terminal, a second terminal, and a control terminal. The first terminal of the transistor 1235 is coupled to the gate biasing circuitry 1045, the class AB control circuitry 1051, and the buffer circuitry 1115. The second terminal of the transistor 1235 is coupled to the current source circuitry 1225 and the transistor 1245. The control terminal of the transistor 1235 is coupled to the transistor 1230 and the second input of the amplifier circuitry 1200, which supplies the reference voltage.

The transistor 1240 has a first terminal, a second terminal, and a control terminal. The first terminal of the transistor 1240 is coupled to the current mirror circuitry 1033, the class AB control circuitry 1051, and the output driver circuitry 1054. The second terminal of the transistor 1240 is coupled to the resistor 1015 and the transistor 1245. The control terminal of the transistor 1240 is coupled to the current source circuitry 1220 and the transistor 1230.

The transistor 1245 has a first terminal, a second terminal, and a control terminal. The first terminal of the transistor 1245 is coupled to the resistor 1015 and the transistor 1240. The second terminal of the transistor 1245 is coupled to the current mirror circuitry 1036, the class AB control circuitry 1051, and the output driver circuitry 1054. The control terminal of the transistor 1245 is coupled to the current source circuitry 1225 and the transistor 1235.

In the example of FIG. 12, the transistors 1063, 1066, 1075, 1078, 1081, 1090, 1130, 1135, 1140, 1235, 1240 are NPN BJTs. Alternatively, the transistors 1063, 1066, 1075, 1078, 1081, 1090, 1130, 1135, 1140, 1235, 1240 may be n-channel FETs, n-channel IGBTs, n-channel JFETs, n-channel MOSFETs or, with slight modifications, p-type equivalent devices. In the example of FIG. 12, the transistors 1057, 1060, 1069, 1072, 1084, 1087, 1120, 1125, 1145, 1230, 1245 are PNP BJTs. Alternatively, the transistors 1057, 1060, 1069, 1072, 1084, 1087, 1120, 1125, 1145, 1230, 1245 may be p-channel FETs, p-channel IGBTs, p-channel JFETs, p-channel MOSFETs, or, with slight modifications, N-type equivalent devices. The transistors 1057, 1060, 1063, 1066, 1069, 1072, 1075, 1078, 1081, 1084, 1087, 1090, 1120, 1125, 1130, 1135, 1140, 1145, 1230, 1235, 1240, 1245 may be depletion mode devices, drain-extended devices, enhancement mode devices, natural transistors or other type of device structure transistors. Furthermore, the transistors 1057, 1060, 1063, 1066, 1069, 1072, 1075, 1078, 1081, 1084, 1087, 1090, 1120, 1125, 1130, 1135, 1140, 1145, 1230, 1235, 1240, 1245 may be implemented in/over a silicon substrate (Si), a silicon carbide substrate (SiC), a gallium nitride substrate (GaN) or a gallium arsenide substrate (GaAs).

As illustrated in FIG. 12 or in examples in which the sizing of the transistors 1120, 1125, 1130, 1135 in Equations (4) and (5) cannot be achieved, using BJTs to implement transistors of the amplifier circuitry 1200 cancels the bias dependency on the input voltage. Advantageously, using BJTs to implement the amplifier circuitry 1200 does not require sizing constraints of Equations (4) and (5). Advantageously, as shown in FIG. 12, the transistors 1230, 1235 may additionally couple the gate biasing circuitry 1045, 1048 to the current source circuitry 1220, 1225. Advantageously, currents of the current source circuitry 1220, 1225 of the buffer circuitry 1215 may be structured to provide additional bias currents to the gate biasing circuitry 1045, 1048. Advantageously, additional current from the transistors 1230, 1235 increases the bias currents of the gate biasing circuitry 1045, 1048, which improves immunity to bias disturbance.

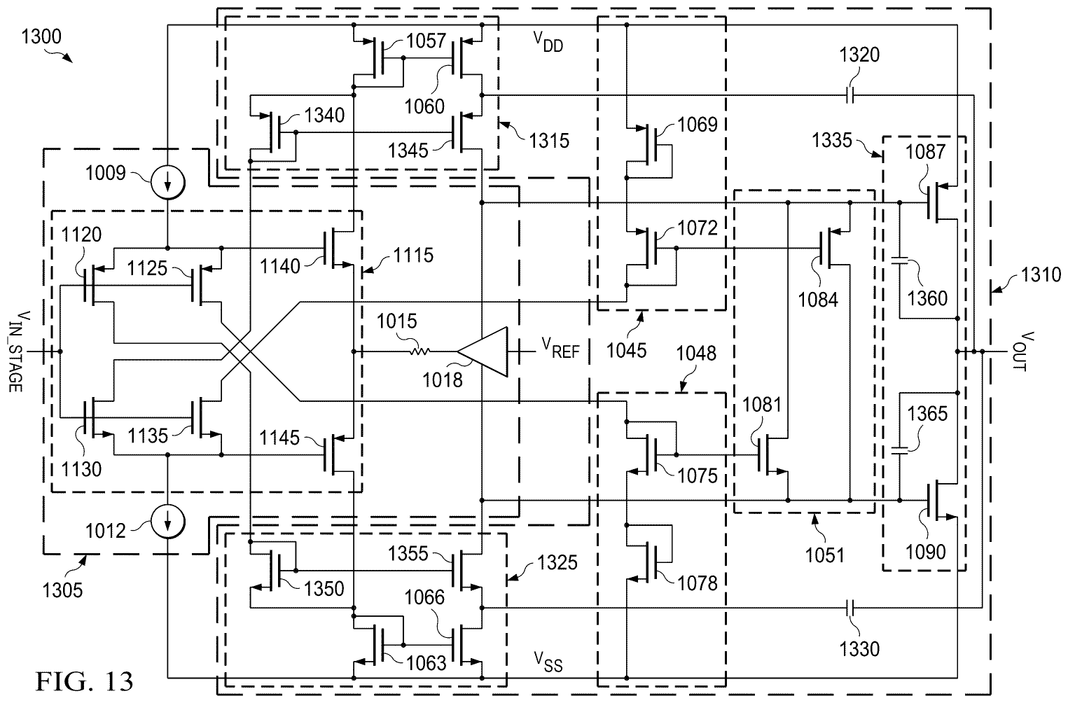

FIG. 13 is a schematic diagram of example amplifier circuitry 1300 including an example opposed-buffer stage 1305, which is another example of the opposed-buffer stages 120, 205, 300, 400, 500, 610, 1003, 1105, 1205 of FIGS. 1, 2, 3, 4, 5, 6, 10, 11, and 12, and an example output stage 1310, which is another example of the output stage 130, 210, 1006, 1110, 1210 of FIGS. 1, 2, 10, 11, and 12. The example opposed-buffer stage 1305 of FIG. 13 includes the current source circuitry 1009, 1012 of FIG. 10, the resistor 1015 of FIG. 10, and the buffer circuitry 1018, 1115 of FIGS. 10 and 11. The example buffer circuitry 1115 of FIG. 13 includes the transistors 1120, 1125, 1130, 1135, 1140, 1145 of FIG. 11.

The example output stage 1310 of FIG. 13 includes the gate biasing circuitry 1045, 1048 of FIG. 10, the class AB control circuitry 1051 of FIG. 10, first example current mirror circuitry 1315, a first example capacitor 1320, second example current mirror circuitry 1325, a second example capacitor 1330, and example output driver circuitry 1335. The example gate biasing circuitry 1045 of FIG. 13 includes the transistors 1069, 1072 of FIG. 10. The example gate biasing circuitry 1048 of FIG. 13 includes the transistors 1075, 1078 of FIG. 10. The example class AB control circuitry 1051 of FIG. 13 includes the transistors 1081, 1084 of FIG. 10. The example current mirror circuitry 1315 of FIG. 13 includes a first example transistor 1340, a second example transistor 1345, and the transistors 1057, 1060 of FIG. 10. The example current mirror circuitry 1325 of FIG. 13 includes a first example transistor 1350, a second example transistor 1355, and the transistors 1063, 1066 of FIG. 10. The example output driver circuitry 1335 of FIG. 13 includes the transistors 1087, 1090 of FIG. 10, a first example capacitor 1360, and a second example capacitor 1365.

The amplifier circuitry 1300 has a first input, a second input, and an output. The first input of the amplifier circuitry 1300 is structured to be coupled to the input stages 110, 605 of FIGS. 1 and 6, which supply an input voltage (V_{IN_STAGE}). The second input of the amplifier circuitry 1300 is structured to be coupled to a reference input, which supplies a reference voltage (V_{REF}). The output of the amplifier circuitry 1300 is structured to be coupled to downstream circuitry, which receives an output voltage (V_{OUT}). In the example of FIG. 13, the amplifier circuitry 1300 includes the opposed-buffer stage 1305 and the output stage 1310. However, in some examples the amplifier circuitry 1300 includes an additional stage, such as the input stages 110, 605 of FIGS. 1 and 6.

The current mirror circuitry 1315 has a first terminal, a second terminal, a third terminal, a fourth terminal, and a fifth terminal. The first terminal of the current mirror circuitry 1315 is coupled to the transistor 1130. The second terminal of the current mirror circuitry 1315 is coupled to the transistor 1140. The third terminal of the current mirror circuitry 1315 is coupled to the buffer circuitry 1018, the class AB control circuitry 1051, and the output driver circuitry 1335. The fourth terminal of the current mirror circuitry 1315 is coupled to the capacitor 1320. The fifth terminal of the current mirror circuitry 1315 is coupled to the supply terminal, which supplies the supply voltage.

The capacitor 1320 has a first terminal and a second terminal. The first terminal of the capacitor 1320 is coupled to the current mirror circuitry 1315. The second terminal of the capacitor 1320 is coupled to the capacitor 1330, the output driver circuitry 1335, and the output of the amplifier circuitry 1300.

The current mirror circuitry 1325 has a first terminal, a second terminal, a third terminal, a fourth terminal, and a fifth terminal. The first terminal of the current mirror circuitry 1325 is coupled to the transistor 1120. The second terminal of the current mirror circuitry 1325 is coupled to the transistor 1145. The third terminal of the current mirror circuitry 1325 is coupled to the buffer circuitry 1018, the class AB control circuitry 1051, and the output driver circuitry 1335. The fourth terminal of the current mirror circuitry 1325 is coupled to the capacitor 1330. The fifth terminal of the current mirror circuitry 1325 is coupled to the common terminal, which supplies the common potential.

The capacitor 1330 has a first terminal and a second terminal. The first terminal of the capacitor 1330 is coupled to the current mirror circuitry 1325. The second terminal of the capacitor 1330 is coupled to the capacitor 1320, the output driver circuitry 1335, and the output of the amplifier circuitry 1300.

The output driver circuitry 1335 has a first terminal, a second terminal, a third terminal, a fourth terminal, and a fifth terminal. The first terminal of the output driver circuitry 1335 is coupled to the supply terminal, which supplies the supply voltage. The second terminal of the output driver circuitry 1335 is coupled to the buffer circuitry 1018, the class AB control circuitry 1051, and the current mirror circuitry 1315. The third terminal of the output driver circuitry 1335 is coupled to the buffer circuitry 1018, the class AB control circuitry 1051, and the current mirror circuitry 1325. The fourth terminal of the output driver circuitry 1335 is coupled to the capacitors 1320, 1330 and the output of the amplifier circuitry 1300. The fifth terminal of the output driver circuitry 1335 is coupled to the common terminal, which supplies the common potential.

The transistor 1340 has a first terminal, a second terminal, and a control terminal. The first terminal of the transistor 1340 is coupled to the transistors 1057, 1060, 1140. The second and control terminals of the transistor 1340 are coupled to the transistors 1130, 1345.

The transistor 1345 has a first terminal, a second terminal, and a control terminal. The first terminal of the transistor 1345 is coupled to the transistor 1060 and the capacitor 1320. The second terminal of the transistor 1345 is coupled to the buffer circuitry 1018, the class AB control circuitry 1051, and the output driver circuitry 1335. The control terminal of the transistor 1345 is coupled to the transistors 1130, 1340.

The transistor 1350 has a first terminal, a second terminal, and a control terminal. The first and control terminals of the transistor 1350 are coupled to the transistors 1120, 1355. The second terminal of the transistor 1350 is coupled to the transistors 1063, 1066, 1145.

The transistor 1355 has a first terminal, a second terminal, and a control terminal. The first terminal of the transistor 1355 is coupled to the buffer circuitry 1018, the class AB control circuitry 1051, and the output driver circuitry 1335. The second terminal of the transistor 1355 is coupled to the transistor 1066 and the capacitor 1330. The control terminal of the transistor 1355 is coupled to the transistors 1120, 1350.

The capacitor 1360 has a first terminal and a second terminal. The first terminal of the capacitor 1360 is coupled to the buffer circuitry 1018 and the transistors 1081, 1084, 1087, 1345. The second terminal of the capacitor 1360 is coupled to the transistors 1087, 1090, the capacitor 1365, and the output terminal of the amplifier circuitry 1300, which supplies the output voltage.

The capacitor 1365 has a first terminal and a second terminal. The first terminal of the capacitor 1365 is coupled to the transistors 1087, 1090, the capacitor 1360, and the output of the amplifier circuitry 1300, which supplies the output voltage. The second terminal of the capacitor 1365 is coupled to the buffer circuitry 1018 and the transistors 1081, 1084, 1090, 1355.

In the example of FIG. 13, the transistors 1063, 1066, 1075, 1078, 1081, 1090, 1130, 1135, 1140, 1350, 1355 are n-channel MOSFETs. Alternatively, the transistors 1063, 1066, 1075, 1078, 1081, 1090, 1130, 1135, 1140, 1350, 1355 may be n-channel FETs, n-channel IGBTs, n-channel JFETs, NPN BJTs or, with slight modifications, p-type equivalent devices. In the example of FIG. 13, the transistors 1057, 1060, 1069, 1072, 1084, 1087, 1120, 1125, 1145, 1340, 1345 are p-channel MOSFETs. Alternatively, the transistors 1057, 1060, 1069, 1072, 1084, 1087, 1120, 1125, 1145, 1340, 1345 may be p-channel FETs, p-channel IGBTs, p-channel JFETs, PNP BJTs, or, with slight modifications, N-type equivalent devices. The transistors 1057, 1060, 1063, 1066, 1069, 1072, 1075, 1078, 1081, 1084, 1087, 1090, 1120, 1125, 1130, 1135, 1140, 1145, 1340, 1345, 1350, 1355 may be depletion mode devices, drain-extended devices, enhancement mode devices, natural transistors or other type of device structure transistors. Furthermore, the transistors 1057, 1060, 1063, 1066, 1069, 1072, 1075, 1078, 1081, 1084, 1087, 1090, 1120, 1125, 1130, 1135, 1140, 1145, 1340, 1345, 1350, 1355 may be implemented in/over a silicon substrate (Si), a silicon carbide substrate (SiC), a gallium nitride substrate (GaN) or a gallium arsenide substrate (GaAs).

In example operation, the transistors 1340, 1350 bias the control terminals of transistors 1345, 1355 responsive to bias current from the transistors 1120, 1130. The transistors 1345, 1355 are cascode transistors, which allow the capacitors 1320, 1330 to be coupled between the output of the amplifier circuitry 1300 and the transistors 1057, 1060, 1063, 1066, which mirror the inverting sink current and the non-inverting source current. In some examples, the capacitors 1320, 1330 may be referred to as Ahuja compensation capacitors. Similar to the Miller compensation of the capacitors 1360, 1365, the capacitors 1320, 1330 frequency compensate the amplifier circuitry 1300. In such examples, the capacitance of capacitors 1320, 1330 displaces some or all of the capacitance of the capacitors 1360, 1365. Advantageously, by enabling the capacitance of the capacitors 1360, 1365 to be reduced or eliminated, using capacitors 1320, 1330 improves the linearity of amplifier circuitry 1300. Advantageously, using the current source circuitry 1009, 1012 to bias the transistors 1345, 1355 reduces the need for additional current sources to bias the transistors 1340, 1350. Advantageously, reducing the number of instances of current source circuitry reduces power consumption, system on chip size, cost, complexity, etc. Advantageously, using the current source circuitry 1009, 1012 rather than currents from transistors 1140, 1145 to bias the transistors 1345, 1355 increases the drain-to-source voltages of transistors 1140, 1145, enabling a lower supply voltage to be used for amplifier circuitry 1300.

FIG. 14 is a flowchart representative of example machine-readable instructions or example operations 1400 that may be at least one of executed, instantiated, or performed using an example implementation of the opposed-buffer stages 120, 1003, 1105, 1205, 1305 of FIGS. 1, 10, 11, 12, and 13 and the output stages 130, 1006, 1110, 1210, 1310 of FIGS. 1, 10, 11, 12, and 13 or more generally the amplifier circuitry 100, 1000, 1100, 1200, 1300 of FIGS. 1, 10, 11, 12, and 13.

The example operations 1400 of FIG. 14 begin at Block 1405 at which the amplifier circuitry 100, 1000, 1100, 1200, 1300 receives an input voltage at inputs of the input stage. In example operations, the transconductance circuitry 615 of FIG. 6 produces currents responsive to a voltage difference between inverting and non-inverting inputs of the amplifier circuitry 100, 1000, 1100, 1200, 1300. In such example operations, the transistors 625, 650 of FIG. 6 supply the difference between the currents of the transconductance circuitry 615 and currents of the current source circuitry 620, 645 of FIG. 6 to inputs of the opposed-buffer stage 120, 205, 300, 400, 500, 610, 1003, 1105, 1205, 1305.

The input stage 110, 605 of FIGS. 1 and 6 generates a differential pair of voltages based on the input voltage. (Block 1410). In some examples, the currents through and the transconductances of the transistors 625, 635, 650, 660 set the input of the opposed-buffer stage 120, 205, 300, 400, 500, 610, 1003, 1105, 1205, 1305 proportional to the voltage difference between the inverting and non-inverting inputs of the amplifier circuitry 100, 1000, 1100, 1200, 1300. In other examples, such as FIG. 6, one input of the opposed-buffer stage 120, 205, 300, 400, 500, 610, 1003, 1105, 1205, 1305 may be fixed and the input stage 110, 605 generates the differential voltage responsive to setting the voltage at the second input of the opposed-buffer stage 120, 205, 300, 400, 500, 610, 1003, 1105, 1205, 1305.

The buffer circuitry 1008, 1115 of FIGS. 10, 11, 12, and 13 generates first and second currents using first and second bias currents and the pair of differential voltages. (Block 1415). In example operations, the transistors 1021, 1120, 1125 of FIGS. 10, 11, 12, and 13 and the current source circuitry 1009 of FIGS. 10, 11, 12, and 13 are structured to form voltage source circuitry which controls the transistors 1027, 1140 of FIGS. 10, 11, 12, and 13 by offsetting the input voltage (V_{IN_STAGE}). For example, in some examples, such as in FIGS. 3, 4, and 5, the current source circuitry 1009 and the transistors 1021, 1120, 1125 may be illustrated and described as voltage source circuitry, such as the voltage source circuitry 330 of FIGS. 3, 4, and 5. In such example operations, the transistors 1027, 1140 conduct the inverting sink current (I_{SNK-}) responsive to the voltage of the transistors 1021, 1120, 1125 and the current source circuitry 1009.

Similarly, the transistors 1024, 1130, 1135 of FIGS. 10, 11, 12, and 13 and the current source circuitry 1012 of FIGS. 10, 11, 12, and 13 are structured to form voltage source circuitry which controls the transistors 1030, 1145 of FIGS. 10, 11, 12, and 13 by offsetting the input voltage (V_{IN_STAGE}). For example, in some examples, such as in FIGS. 3, 4, and 5, the current source circuitry 1012 and the transistors 1024, 1130, 1135 may be illustrated and described as voltage source circuitry, such as the voltage source circuitry 335 of FIGS. 3, 4, and 5. In such example operations, the transistors 1030, 1145 conduct the non-inverting source current (I_{SRC+}) responsive to the voltage of the transistors 1024, 1130, 1135 and the current source circuitry 1012.

The buffer circuitry 1018, 1215 of FIGS. 10, 11, 12, and 13 generates third and fourth currents using third and fourth bias currents and the pair of differential voltages. (Block 1420). In example operations, the transistor 1230 of FIG. 12 and the current source circuitry 1220 of FIG. 12 are structured to form voltage source circuitry which controls the transistor 1240 of FIG. 12 by offsetting the reference voltage (V_{REF}). For example, in some examples, such as in FIGS. 3, 4, and 5, the current source circuitry 1220 and the transistor 1230 may be illustrated and described as voltage source circuitry, such as the voltage source circuitry 350 of FIGS. 3, 4, and 5. In such example operations, the transistor 1240 conducts the non-inverting sink current (I_{SNK+}) responsive to the voltage of the transistor 1230 and the current source circuitry 1220.

Similarly, the transistor 1235 of FIG. 12 and the current source circuitry 1225 of FIG. 12 are structured to form voltage source circuitry, which controls the transistor 1245 of FIG. 12 by offsetting the reference voltage (V_{REF}). For example, in some examples, such as in FIGS. 3, 4, and 5, the current source circuitry 1225 and the transistor 1235 may be illustrated and described as voltage source circuitry, such as the voltage source circuitry 355 of FIGS. 3, 4, and 5. In such example operations, the transistor 1245 conducts the inverting source current (I_{SRC-}) responsive to the voltage of the transistor 1235 and the current source circuitry 1225. The buffer circuitry 1215 of FIG. 12 represents an example implementation of the buffer circuitry 1018 in the examples of FIGS. 10, 11, and 13. In some examples, the opposed-buffer stage 1003, 1105, 1205, 1305 may be modified to illustrate one or more components of the buffer circuitry 1215 externally to the buffer circuitry 1018.

The gate biasing circuitry 1045 of FIGS. 10, 11, 12, and 13 biases a first gate using at least a portion of the second bias current. (Block 1425). In some examples, the transistors 1024, 1135 couple the gate biasing circuitry 1045 to the current source circuitry 1012. In such examples, the current source circuitry 1012 sinks current through the transistors 1024, 1069, 1072, 1135 of FIGS. 10, 11, 12, and 13. In example operations, the current source circuitry 1012 biases the control terminal of the transistor 1084 of FIGS. 10, 11, 12, and 13 to a voltage approximately equal to the supply voltage (V_{DD}) minus the gate-to-source voltages of the transistors 1069, 1072. Advantageously, using the current source circuitry 1012 to bias the transistor 1084 reduces the need for an additional current source to bias the transistors 1069, 1072. Advantageously, reducing the number of instances of current source circuitry reduces power consumption, system on chip size, cost, complexity, etc.

The gate biasing circuitry 1048 of FIGS. 10, 11, 12, and 13 biases a second gate using at least a portion of the first bias current. (Block 1430). In some examples, the transistors 1021, 1125 couple the gate biasing circuitry 1048 to the current source circuitry 1009. In such examples, the current source circuitry 1009 supplies current through the transistors 1021, 1075, 1078, 1125 of FIGS. 10, 11, 12, and 13. In example operations, the current source circuitry 1009 biases the control terminal of the transistor 1081 of FIGS. 10, 11, 12, and 13 to a voltage approximately equal to the common potential (V_{SS}) plus the gate-to-source voltages of the transistors 1075, 1078. Advantageously, using the current source circuitry 1009 to bias the transistor 1081 reduces the need for an additional current source to bias the transistors 1075, 1078. Advantageously, reducing the number of instances of current source circuitry reduces power consumption, system on chip size, cost, complexity, etc.

The current mirror circuitry 1033, 1315 of FIGS. 10, 11, 12, and 13 and the class AB control circuitry 1051 of FIGS. 10, 11, 12, and 13 control a high-side output transistor using at least a portion of the first bias current and the first and third currents. (Block 1435). In example operations, the current mirror circuitry 1033, 1315 mirrors at least the inverting sink current. In some examples, such as in FIGS. 11, 12, and 13, the current mirror circuitry 1033, 1315 mirrors the inverting sink current through the transistor 1140 and a portion of the current sunk by the current source circuitry 1012. For example, the transistor 1130 coupled to the current source circuitry 1012 to the current mirror circuitry 1033, 1315, which boosts the current at the output of the current mirror circuitry 1033, 1315. In such examples, the transistor 1130 or the current source circuitry 1012 may be sized to replace the current source circuitry 1039 of FIG. 10, which biases the transistors 1081, 1084. Advantageously, using the current source circuitry 1012 and the transistor 1130 to bias the class AB control circuitry 1051 replaces the need for the current source circuitry 1039. Advantageously, reducing the number of instances of current source circuitry reduces system on chip size, cost, complexity, etc. In such example operations, the transistors 1081, 1084 set the control terminal of the transistor 1087 of FIGS. 10, 11, 12, and 13 responsive to the difference between the inverting and non-inverting sink currents.

The current mirror circuitry 1036, 1325 of FIGS. 10, 11, 12, and 13 and the class AB control circuitry 1051 controls a low-side output transistor using at least a portion of the second bias current and the second and fourth currents. (Block 1440). In example operations, the current mirror circuitry 1036, 1325 mirrors at least the non-inverting source current. In some examples, such as in FIGS. 11, 12, and 13, the current mirror circuitry 1036, 1325 mirrors the non-inverting source current through the transistor 1145 and a portion of the current sourced by the current source circuitry 1009. For example, the transistor 1120 coupled to the current source circuitry 1009 to the current mirror circuitry 1036, 1325, which boosts the current at the output of the current mirror circuitry 1036, 1325. In such examples, the transistor 1120 or the current source circuitry 1009 may be sized to replace the current source circuitry 1042 of FIG. 10, which biases the transistors 1081, 1084. Advantageously, using the current source circuitry 1009 and the transistor 1120 to bias the class AB control circuitry 1051 replaces the need for the current source circuitry 1042. Advantageously, reducing the number of instances of current source circuitry reduces system on chip size, cost, complexity, etc. In such example operations, the transistors 1081, 1084 set the control terminal of the transistor 1090 of FIGS. 10, 11, 12, and 13 responsive to the difference between the inverting and non-inverting source currents.

Control proceeds to return to Block 1405. Example methods are described with reference to the flowchart illustrated in FIG. 14. However, many other methods of implementing the opposed-buffer stages 120, 1003, 1105, 1205, 1305 of FIGS. 1, 10, 11, 12, and 13 and the output stages 130, 1006, 1110, 1210, 1310 of FIGS. 1, 10, 11, 12, and 13 or more generally the amplifier circuitry 100, 1000, 1100, 1200, 1300 of FIGS. 1, 10, 11, 12, and 13 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. An apparatus comprising:
buffer circuitry including:
a first transistor having a first terminal, a second terminal, and a control terminal;
a second transistor having a first terminal, a second terminal, and a control terminal, the control terminal of the second transistor coupled to the control terminal of the first transistor;
a third transistor having a first terminal and a control terminal, the control terminal of the third transistor coupled to the first terminal of the first transistor; and
a fourth transistor having a first terminal and a control terminal, the first terminal of the fourth transistor coupled to the first terminal of the third transistor, the control terminal of the fourth transistor coupled to the first terminal of the second transistor; and
output stage circuitry including:
first gate biasing circuitry having a terminal coupled to the second terminal of the first transistor;
second gate biasing circuitry having a terminal coupled to the second terminal of the second transistor;
a fifth transistor having a control terminal coupled to the second terminal of the first transistor and the terminal of the first gate biasing circuitry; and
a sixth transistor having a control terminal coupled to the second terminal of the second transistor and the terminal of the second gate biasing circuitry.

2. The apparatus of claim 1, the buffer circuitry further including:
a seventh transistor having a first terminal and a control terminal, the first terminal of the seventh transistor coupled to the first terminal of the first transistor and the control terminal of the third transistor; and
an eighth transistor having a first terminal and a control terminal, the first terminal of the eighth transistor coupled to the first terminal of the second transistor and the control terminal of the fourth transistor, the control terminal of the eighth transistor coupled to the control terminal of the first transistor, the control terminal of the second transistor, and the control terminal of the seventh transistor.

3. The apparatus of claim 2, wherein the fifth transistor further has a first terminal and a second terminal, the sixth transistor further has a first terminal and a second terminal, the seventh transistor further has a second terminal, the eighth transistor further has a second terminal, and the apparatus further comprising:
first current mirror circuitry having an input and an output, the input of the first current mirror circuitry coupled to the second terminal of the seventh transistor, the output of the first current mirror circuitry coupled to the first terminal of the fifth transistor and the first terminal of the sixth transistor; and
second current mirror circuitry having an input and an output, the input of the second current mirror circuitry coupled to the second terminal of the eighth transistor, the output of the second current mirror circuitry coupled to the second terminal of the fifth transistor and the second terminal of the sixth transistor.

4. The apparatus of claim 3, wherein the buffer circuitry is first buffer circuitry, the first gate biasing circuitry further has an output, and the apparatus further comprising:
second buffer circuitry having an output, a first supply terminal, and a second supply terminal, the output of the second buffer circuitry coupled to the first terminal of the third transistor and the first terminal of the fourth transistor; and
output driver circuitry having a first terminal and a second terminal, the first terminal of the output driver circuitry coupled to the first terminal of the fifth transistor, the first terminal of the sixth transistor, the output of the first current mirror circuitry, and the first supply terminal of the second buffer circuitry, the second terminal of the output driver circuitry coupled to the second terminal of the fifth transistor, the second terminal of the sixth transistor, the output of the second current mirror circuitry, and the second supply terminal of the second buffer circuitry.

5. The apparatus of claim 1, wherein the fifth transistor further has a first terminal and a second terminal, the sixth transistor further has a first terminal and a second terminal, and the apparatus further comprising output driver circuitry having a first terminal and a second terminal, the first terminal of the output driver circuitry coupled to the first terminal of the fifth transistor and the first terminal of the sixth transistor, the second terminal of the output driver circuitry coupled to the second terminal of the fifth transistor and the second terminal of the sixth transistor.

6. The apparatus of claim 5, wherein the output driver circuitry includes:
a seventh transistor having a first terminal and a control terminal, the control terminal of the seventh transistor coupled to the first terminal of the fifth transistor and the first terminal of the sixth transistor; and
an eighth transistor having a first terminal and a control terminal, the first terminal of the eighth transistor coupled to the first terminal of the seventh transistor, and the control terminal of the eighth transistor coupled to the second terminal of the fifth transistor and the second terminal of the sixth transistor.

7. The apparatus of claim 1, wherein the first gate biasing circuitry includes:
a seventh transistor having a first terminal and a control terminal; and
an eighth transistor having a first terminal, a second terminal, and a control terminal, the first terminal of the eighth transistor coupled to the first terminal of the seventh transistor and the control terminal of the seventh transistor, the second terminal of the eighth transistor coupled to the second terminal of the first transistor and the control terminal of the eighth transistor.

8. The apparatus of claim 1, wherein the buffer circuitry is first buffer circuitry, and the apparatus further comprising:
second buffer circuitry having an input and an output, the output of the second buffer circuitry coupled to the first terminal of the third transistor and the first terminal of the fourth transistor;
third buffer circuitry having an input and an output, the input of the third buffer circuitry coupled to the input of the second buffer circuitry; and
switch circuitry having a first terminal and a second terminal, the first terminal of the switch circuitry coupled to the output of the third buffer circuitry, the second terminal of the switch circuitry coupled to the control terminal of the first transistor and the control terminal of the second transistor.

9. An apparatus comprising:
buffer circuitry including:
a first transistor having a first terminal, a second terminal, and a control terminal;
a second transistor having a first terminal, a second terminal, and a control terminal, the control terminal of the second transistor coupled to the control terminal of the first transistor;
a third transistor having a first terminal, a second terminal, and a control terminal, the control terminal of the third transistor coupled to the first terminal of the first transistor; and
a fourth transistor having a first terminal, a second terminal, and a control terminal, the first terminal of the fourth transistor coupled to the first terminal of the third transistor, the control terminal of the fourth transistor coupled to the first terminal of the second transistor;
first current mirror circuitry having an input and an output, the input of the first current mirror circuitry coupled to the second terminal of the first transistor and the second terminal of the fourth transistor;
second current mirror circuitry having an input and an output, the input of the second current mirror circuitry coupled to the second terminal of the second transistor and the second terminal of the third transistor;
a fifth transistor having a first terminal and a control terminal, the control terminal of the fifth transistor coupled to the output of the first current mirror circuitry; and
a sixth transistor having a first terminal and a control terminal, the first terminal of the sixth transistor coupled to the first terminal of the fifth transistor, the control terminal of the sixth transistor coupled to the output of the second current mirror circuitry.

10. The apparatus of claim 9, the buffer circuitry further including:
a seventh transistor having a first terminal and a control terminal, the first terminal of the seventh transistor coupled to the first terminal of the first transistor and the control terminal of the third transistor; and
an eighth transistor having a first terminal and a control terminal, the first terminal of the eighth transistor coupled to the first terminal of the second transistor and the control terminal of the fourth transistor, the control terminal of the eighth transistor coupled to the control terminal of the first transistor, the control terminal of the second transistor, and the control terminal of the seventh transistor.

11. The apparatus of claim 10, wherein the seventh transistor further has a second terminal, the eighth transistor further has a second terminal, and the apparatus further comprising:
first gate biasing circuitry having a terminal coupled to the second terminal of the seventh transistor; and
second gate biasing circuitry having a terminal coupled to the second terminal of the eighth transistor.

12. The apparatus of claim 11, wherein the buffer circuitry is first buffer circuitry, and the apparatus further comprising:
second buffer circuitry having an output and a supply terminal, the output of the second buffer circuitry coupled to the first terminal of the third transistor and the first terminal of the fourth transistor; and
class AB control circuitry having a first terminal, a second terminal, a third terminal, and fourth terminal, the first terminal of the class AB control circuitry coupled to the output of the first current mirror circuitry and the control terminal of the fifth transistor, the second terminal of the class AB control circuitry coupled to the output of the second current mirror circuitry and the control terminal of the sixth transistor, the third terminal of the class AB control circuitry coupled to the second terminal of the seventh transistor and the terminal of the first gate biasing circuitry, the fourth terminal of the class AB control circuitry coupled to the second terminal of the eighth transistor and the terminal of the second gate biasing circuitry.

13. The apparatus of claim 9, further comprising class AB control circuitry having a first terminal and a second terminal, the first terminal of the class AB control circuitry coupled to the output of the first current mirror circuitry and the control terminal of the fifth transistor, the second terminal of the class AB control circuitry coupled to the output of the second current mirror circuitry and the control terminal of the sixth transistor.

14. The apparatus of claim 13, wherein the class AB control circuitry includes:
a seventh transistor having a first terminal and a second terminal; and
an eighth transistor having a first terminal and a second terminal, the first terminal of the eighth transistor coupled to the output of the first current mirror circuitry, the control terminal of the fifth transistor, and the first terminal of the seventh transistor, the second terminal of the eighth transistor coupled to the output of the second current mirror circuitry, the control terminal of the sixth transistor, and the second terminal of the seventh transistor.

15. The apparatus of claim 9, wherein the first current mirror circuitry includes:
a seventh transistor having a first terminal and a control terminal; and
an eighth transistor having a control terminal coupled to the second terminal of the first transistor, the second terminal of the fourth transistor, the first terminal of the seventh transistor, and the control terminal of the seventh transistor.

16. The apparatus of claim 9, wherein the buffer circuitry is first buffer circuitry, and the apparatus further comprising:
second buffer circuitry having an input and an output, the output of the second buffer circuitry coupled to the first terminal of the third transistor and the first terminal of the fourth transistor;
third buffer circuitry having an input and an output, the input of the third buffer circuitry coupled to the input of the second buffer circuitry; and
switch circuitry having a first terminal and a second terminal, the first terminal of the switch circuitry coupled to the output of the third buffer circuitry, the second terminal of the switch circuitry coupled to the control terminal of the first transistor and the control terminal of the second transistor.

17. An apparatus comprising:
buffer circuitry including:
a first transistor having a first terminal, a second terminal, and a control terminal; and
a second transistor having a first terminal, a second terminal, and a control terminal, the first terminal of the second transistor coupled to the first terminal of the first transistor, the control terminal of the second transistor coupled to the control terminal of the first transistor;
output stage circuitry including:
gate biasing circuitry having a terminal;
a third transistor having a first terminal and a control terminal, the control terminal of the third transistor coupled to the second terminal of the second transistor and the terminal of the gate biasing circuitry;
current mirror circuitry having an input and an output, the input of the current mirror circuitry coupled to the second terminal of the first transistor; and
a fourth transistor having a control terminal coupled to the output of the current mirror circuitry and the first terminal of the third transistor.

18. The apparatus of claim 17, wherein the buffer circuitry further includes a fifth transistor having a first terminal coupled to the second terminal of the first transistor and the input of the current mirror circuitry.

19. The apparatus of claim 18, wherein the buffer circuitry is first buffer circuitry, the third transistor further has a second terminal, the fourth transistor further has a first terminal, the fifth transistor further has a second terminal, and the apparatus further comprising:
second buffer circuitry having an output and a supply terminal, the output of the second buffer circuitry coupled to the second terminal of the fifth transistor;
a sixth transistor having a first terminal and a second terminal, the first terminal of the sixth transistor coupled to the output of the current mirror circuitry, the control terminal of the fourth transistor, and the supply terminal of the second buffer circuitry; and
a seventh transistor having a first terminal and a control terminal, the first terminal of the seventh transistor coupled to the first terminal of the fourth transistor, the control terminal of the seventh transistor coupled to the second terminal of the third transistor and the second terminal of the sixth transistor.

20. The apparatus of claim 17, the buffer circuitry further including:
a fifth transistor having a first terminal and a control terminal; and
a sixth transistor having a first terminal and a control terminal, the first terminal of the sixth transistor coupled to the first terminal of the fifth transistor, the control terminal of the sixth transistor coupled to the control terminal of the first transistor, the control terminal of the second transistor, and the control terminal of the fifth transistor.
